(19) United States
(12) Patent Application Publication
(10) Pub. No.: US 2006/0087016 A1
(43) Pub. Date: Apr. 27, 2006

(54) IC (integrated circuit) card

(75) Inventors: Tamaki Wada, Higashimurayama (JP); Hirotaka Nishizawa, Fuchu (JP); Michiaki Sugiyama, Tokyo (JP); Junichiro Osako, Kodaira (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/251,961

(22) Filed: Oct. 18, 2005

(30) Foreign Application Priority Data
Oct. 22, 2004 (JP) 2004-308323

(51) Int. Cl. H01L 23/02

(52) U.S. Cl. 257/679

(57) ABSTRACT

An IC card according to the present invention reduces or prevents a deterioration or damage on an electronic device to which the IC card is mounted. A buffer section made of a thermoplastic resin formed by a plastic injection molding is provided at the outer peripheral face of a memory card whose appearance is partly composed of a sealing section made of a thermosetting resin formed by a transfer molding without providing a cap. The buffer section has a taper formed at the outer peripheral corner, and further, the buffer section is softer than the sealing section and has a smooth surface. When the memory card is mounted to an electronic device, the buffer section is brought into contact with connector pins or a guide rail of a connector of the electronic device, thereby being capable of reducing or preventing the deterioration or damage on the connector.

### CROSS-REFERENCE TO RELATED APPLICATION

The present application claims priority from Japanese patent application No. 2004-308323 filed on Oct. 22, 2004, the content of which is hereby incorporated by reference into this application.

### BACKGROUND OF THE INVENTION

The present invention relates to an IC (Integrated circuit) card and its manufacturing technique, and more particularly to a technique effective for being applied to a memory card such as, for example, a multi media card (there is a standard standardized by the Multi Media Card Association).

A memory card such as a Multi Media Card (hereinafter referred to as MMC) is a kind of storage devices for storing information into a semiconductor memory chip provided therein. It can make a direct and electrical access to a non-volatile memory of the semiconductor memory chip without requiring a mechanical control, so that it has excellent features such that the writing and reading time are fast compared to the other memory devices, and further that the memory medium is exchangeable. Moreover, such memory card is small-sized and light-weight, so that it is used as an auxiliary memory device of an electronic device that requires portability such as a portable personal computer, cellular phone, digital camera or the like.

The outer appearance of the MMC is formed by a thin plate-like cap having a rectangular plane and having a corner section greatly chamfered. A memory body is fitted and bonded to a recess on a component mounting face of the cap. The memory body has a wiring board and semiconductor chips mounted on its main surface. The semiconductor chips are sealed by a mold resin and electrically connected to plural external terminals on the back face of the wiring board via the wiring of the wiring board. The plural external terminals on the back face of the wiring board are exposed to the outside so as to be electrically connected to an electronic device to which the MMC is to be mounted. It should be noted that the aforesaid MMC is disclosed in, for example, Japanese Unexamined Patent Publication No. 2004-171598, that discloses a configuration of a general MMC having a cap (see Patent Reference 1).

The thickness of the MMC is defined by a standard. The thickness of the MMC having the aforesaid configuration with a cap is composed of four factors, i.e., the thickness of a mold resin, thickness of the wiring board, thickness of a cap and thickness of a bonding agent, whereby it is difficult to adjust the variation provision, thereby entailing a problem of being difficult in the management of manufacture. Further, the aforesaid MMC configuration has a problem of not being capable of coping with further increase in the thickness of the mold resin. Specifically, the semiconductor chip in the MMC has currently a two-layer structure, but the number of the laminated layer in the semiconductor chip will increase in order to cope with the demand for increasing the memory capacity. If the number of the laminated layer in the semiconductor chip increases, the thickness of the mold resin is required to be increased. The thickness of the MMC is defined by a standard value, but the thickness of the cap, thickness of the bonding agent and thickness of the wiring board are reduced to reach the limit thickness, with the result that it is difficult to further increase the thickness of the mold resin.

As a countermeasure for the aforesaid problem, International Publication No. WO2002/069251, for example, discloses a configuration wherein semiconductor chips mounted on a wiring board are sealed by a mold resin, and this wiring board and the mold resin compose an overall outer appearance of a MMC (see Patent Reference 2).

[Patent Reference 1]

Japanese Unexamined Patent Publication No. 2004-171598

[Patent Reference 2]

International Publication No. WO2002/069251

### SUMMARY OF THE INVENTION

The present inventors have found that, when an IC card whose outer appearance is formed of a mold resin is inserted into an electronic device, a part of the IC card is brought into contact with a connector terminal or guide rail section of the electronic device, whereby there is a fear that the connector terminal or guide rail section may be deteriorated or damaged.

Specifically, in case where the IC card is inserted into an electronic device, the corner at the lower section of the front face of the IC card is firstly brought into contact with the connector terminal of the electronic device. In case where the outer appearance of the IC card is formed of a cap, the corner at the lower section of the front face of the cap is chamfered into a round shape and the cap is softer and smoother than the mold resin, resulting in that the connector terminal is not deteriorated or damaged even if the lower section of the front face of the cap is brought into contact with the connector terminal. Further, since the surface of the cap is smooth, the guide rail is not scraped even if the outer periphery of the cap is brought into contact with the guide rail of the connector. On the other hand, in case where the outer appearance of the IC card is formed of a mold resin, there is a fear that the connector terminal is deteriorated or damaged, such as the metal plating on the surface of the connector terminal is peeled off or the connector terminal is broken, when the lower section of the front face of the IC card is brought into contact with the connector terminal. Moreover, when the side face of the IC card is brought into contact with the guide rail of the connector, the guide rail may be scraped or foreign matter are generated due to the scrape of the guide rail. The reasons of this are as follows. In case where the outer appearance of the IC card is formed of a mold resin, a lifting lead for supporting external terminals of the IC card or hard wiring board formed of a glass epoxy resin or the like is present at the lower section of the front face of the IC card, so that the corner at the lower section of the front face of the IC card is angular since it cannot sufficiently be chamfered. The other reason is that the mold resin is harder than the cap since the mold resin includes plural fine fillers, harder than the resin, for decreasing a thermal expansion coefficient or increasing a resin strength. Another reason is that fillers are exposed on the surface of the mold resin, so that the surface of the mold resin is rough and acts as a grindstone.

An object of the present invention is to provide a technique capable of reducing or preventing the deterioration or damage of an electronic device to which an IC card is mounted.

The foregoing and the other objects and novel feature of the present invention will be apparent from the description of the specification and appended drawings.

The following is a brief explanation of a summary of a representative one of the inventions disclosed in this application.

Specifically, the present invention provides an IC card wherein a buffer member is provided at an outer periphery of a card body having a configuration wherein semiconductor chips mounted on a wiring board are sealed by a resin.

[Effect of the Invention]

The effect obtained by the representative one of the inventions disclosed in this application will be briefly explained as follows.

Specifically, an IC card of the present invention is provided with a buffer member formed at an outer periphery of a card body having a configuration wherein semiconductor chips mounted on a wiring board are sealed by a resin, thereby being capable of reducing or preventing the deterioration or damage of a connector terminal or a guide rail of an electronic device to which the IC card is to be mounted.

### BRIEF DESCRIPTION OF THE DRAWINGS

FIG. 1 is an overall plan view of a main surface of an IC card according to one embodiment of the present invention;

FIG. 2 is an overall plan view of a back face of the IC card shown in FIG. 1;

FIG. 3 is a front view of the IC card seen from the direction shown by an arrow A in FIGS. 1 and 2;

FIG. 4 is a rear view of the IC card seen from the direction shown by an arrow B in FIGS. 1 and 2;

FIG. 5 is a side view of the IC card seen from the direction shown by an arrow C in FIGS. 1 and 2;

FIG. 6 is a side view of the IC card seen from the direction shown by an arrow D in FIGS. 1 and 2;

FIG. 7 is a sectional view taken along a line X1-X1 in FIG. 1;

FIG. 8 is an enlarged sectional view of an area AR in FIG. 7;

FIG. 9 is a sectional view taken along a line Y1-Y1;

FIG. 10 is an overall plan view of a main surface of a wiring board of a card body composing the IC card shown in FIG. 1;

FIG. 11 is an overall plan view of the main surface of the wiring board shown in FIG. 10 to which a bonding wire is added;

FIG. 12 is a plan view showing a state when an IC card is inserted into a connector, studied by the present inventors;

FIG. 13 is a sectional view taken along a line X2-X2 in FIG. 12;

FIG. 14 is a plan view showing a state before the IC card in FIG. 1 is inserted into a connector;

FIG. 15 is a sectional view taken along a line X3-X3 in FIG. 14;

FIG. 16 is a sectional view of the IC card that is further pushed from the state shown in FIG. 15 until the lower section of the front face of the IC card is brought into contact with a connector terminal;

FIG. 17 is a plan view of the IC card in FIG. 1 that is fully inserted into the connector;

FIG. 18 is a sectional view taken along a line X4-X4 in FIG. 17;

FIG. 19 is a manufacturing flowchart of the IC card in FIG. 1;

FIG. 20 is an overall plan view of a main surface of a board frame used for manufacturing the IC card in FIG. 1;

FIG. 21 is an overall plan view of a back face of the board frame shown in FIG. 20;

FIG. 22 is a sectional view taken along a line X5-X5 in FIG. 20;

FIG. 23 is an overall plan view of a main surface of a board frame after a mounting process of a semiconductor chip;

FIG. 24 is an enlarged plan view of a unit section of the board frame in FIG. 23;

FIG. 25 is an overall plan view of a main surface of a board frame after a wire bonding process;

FIG. 26 is an enlarged plan view of a unit section of the board frame in FIG. 25;

FIG. 27 is an overall plan view of the board frame after a buffer section is mounted;

FIG. 28 is a sectional view taken along a line X6-X6 in FIG. 27;

FIG. 29 is an enlarged sectional view of a unit section of the board frame in FIG. 28;

FIG. 30 is an overall plan view of the board frame after a mold process;

FIG. 31 is a sectional view taken along a line X7-X7 in FIG. 30;

FIG. 32 is an enlarged sectional view of a unit section of the board frame in FIG. 31;

FIG. 33 is an overall plan view of the board frame that is being subject to a dicing process;

FIG. 34 is a sectional view taken along a line X8-X8 in FIG. 33;

FIG. 35 is an enlarged sectional view of an IC card cut out from the board frame of FIG. 34;

FIG. 36 is an overall plan view of a main surface of an IC card according to another embodiment of the present invention;

FIG. 37 is an overall plan view of a back face of the IC card shown in FIG. 36;

FIG. 38 is a sectional view taken along a line X9-X9 in FIG. 36;

FIG. 39 is a sectional view taken along a line Y2-Y2 in FIG. 36;

FIG. 40 is a sectional view taken along a line Y3-Y3 in FIG. 36;

FIG. 41 is an overall plan view of a main surface of a wiring board composing the IC card in FIG. 36;

FIG. 42 is an overall plan view of the main surface of the wiring board in FIG. 41 to which a bonding wire is added;

FIG. 43 is an overall plan view of a main surface of an IC card according to still another embodiment of the present invention;

FIG. 44 is an overall plan view of a back face of the IC card shown in FIG. 43;

FIG. 45 is a rearview of the IC card seen from the direction shown by an arrow B in FIGS. 43 and 44;

FIG. 46 is a side view of the IC card seen from the direction shown by an arrow D in FIGS. 43 and 44;

FIG. 47 is a sectional view taken along a line Y4-Y4 in FIG. 43;

FIG. 48 is a sectional view taken along a line Y5-Y5 in FIG. 43;

FIG. 49 is a sectional view taken along a line X10-X10 in FIG. 43;

FIG. 50 is a plan view of the main surface of the IC card in FIG. 43 to which a size-changing adapter is mounted;

FIG. 51 is a plan view of a back face of the IC card shown in FIG. 50;

FIG. 52 is a side view of the IC card seen from the direction shown by an arrow D in FIG. 50;

FIG. 53 is a plan view of the IC card in FIG. 43 to which a connector has not yet been mounted;

FIG. 54 is a sectional view taken along a line X11-X11 in FIG. 53;

FIG. 55 is a sectional view of the IC card that is further pushed from the state shown in FIG. 54 until the lower section of the front face of the IC card is brought into contact with connector pins;

FIG. 56 is a plan view of the IC card that is fully inserted into the connector;

FIG. 57 is a sectional view taken along a line X12-X12 in FIG. 56;

FIG. 58 is an overall plan view of a main surface of a board frame used for manufacturing the IC card in FIG. 43;

FIG. 59 is an overall plan view of a back face of the board frame shown in FIG. 58;

FIG. 60 is an overall plan view of the main surface of the board frame in FIG. 58 after a wire bonding process;

FIG. 61 is an overall plan view of the board frame after a buffer section is mounted;

FIG. 62 is an overall plan view of a back face of the board frame shown in FIG. 61;

FIG. 63 is a plan view of a main surface of a buffer section in FIG. 61;

FIG. 64 is a plan view of a back face of the buffer section in FIG. 63;

FIG. 65 is a sectional view taken along a line X14-X14 in FIG. 63;

FIG. 66 is a sectional view taken along a line X15-X15 in FIG. 63;

FIG. 67 is a sectional view taken along a line X16-X16 in FIG. 63;

FIG. 68 is a sectional view taken along a line Y6-Y6 in FIG. 63;

FIG. 69 is an overall plan view of a main surface of an IC card according to another embodiment of the present invention;

FIG. 70 is an overall plan view of a back face of the IC card shown in FIG. 69;

FIG. 71 is a sectional view taken along a line X17-X17 in FIG. 69;

FIG. 72 is an enlarged sectional view of an area AR in FIG. 71;

FIG. 73 is a sectional view taken along a line Y7-Y7 in FIG. 69;

FIG. 74 is a plan view of the main surface of the IC card in FIG. 69 during the manufacturing process; and

FIG. 75 is an enlarged sectional view of an essential part at a bonding section of the IC card in FIG. 74 and the buffer section during the manufacturing process.

### DETAILED DESCRIPTION OF THE PREFERRED EMBODIMENTS

In the following embodiments, descriptions will be made separately to plural sections or embodiments when required. Unless otherwise stated, they are not independent of each other, and one is dependent partially or wholly on others in terms of variants, details, additional descriptions, and the like. In the embodiments below, the number of elements (including count, numeric value, quantity, and range), when designated, are not limited to the designated number and may be around the designated number, except in cases where it is explicitly specified and cases where it is theoretically limited to the specific number. Furthermore, in the embodiments below, it goes without saying that components in the embodiments (including element steps and the like) are not always mandatory, except in cases where they are explicitly specified. Likewise, in the embodiments below, shapes, positional relations, and the like of components and the like, when designated, include those with similarities, except in cases where they are explicitly specified and cases where the similarities are theoretically inappropriate. The same is also true for the above-mentioned numeric values and range. In all drawings for explaining the embodiments, elements having identical functions are identified by the same reference numerals and duplicate descriptions of them are omitted. Hereinafter, embodiments of the present invention will be described with reference to the accompanying drawings.

### Embodiment 1

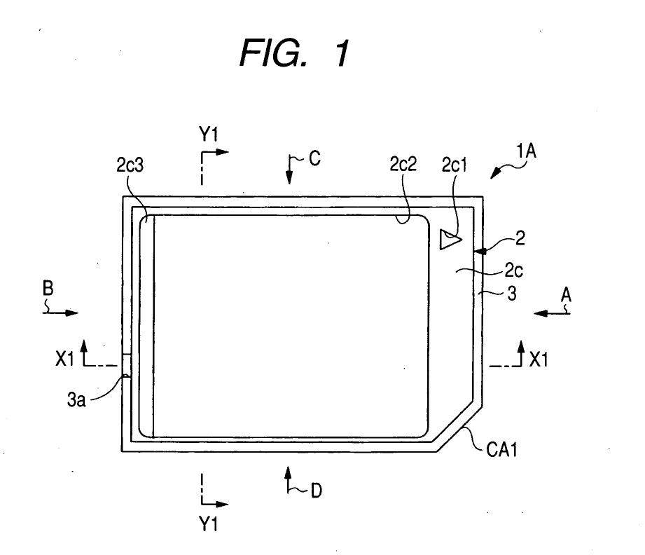

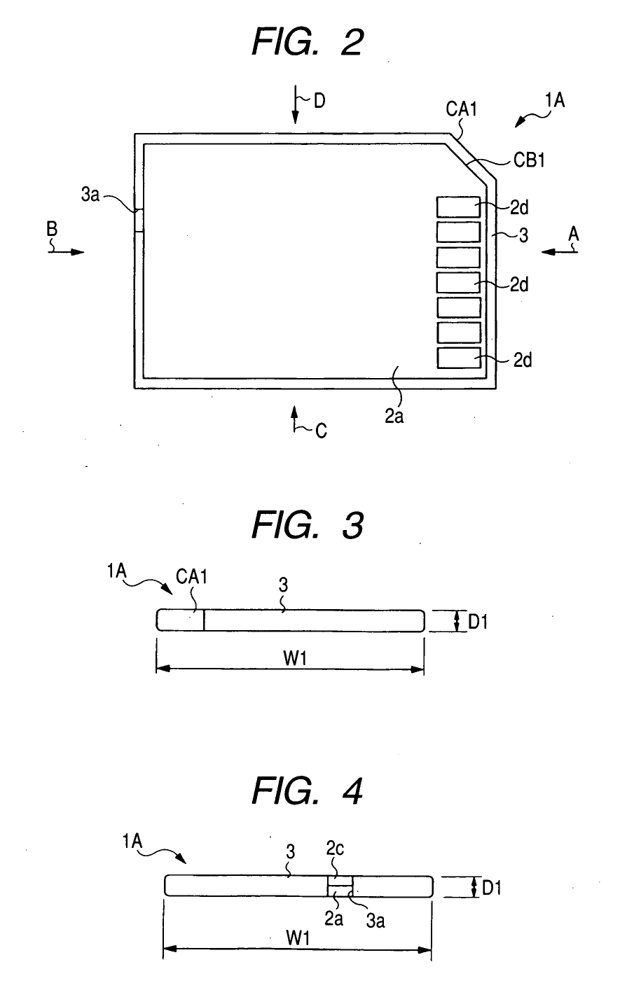

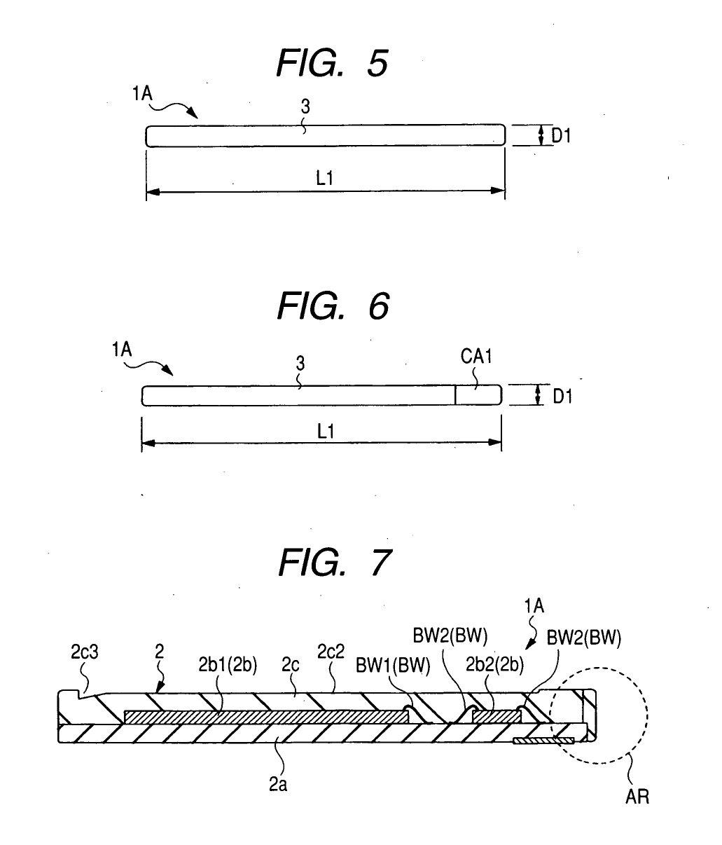

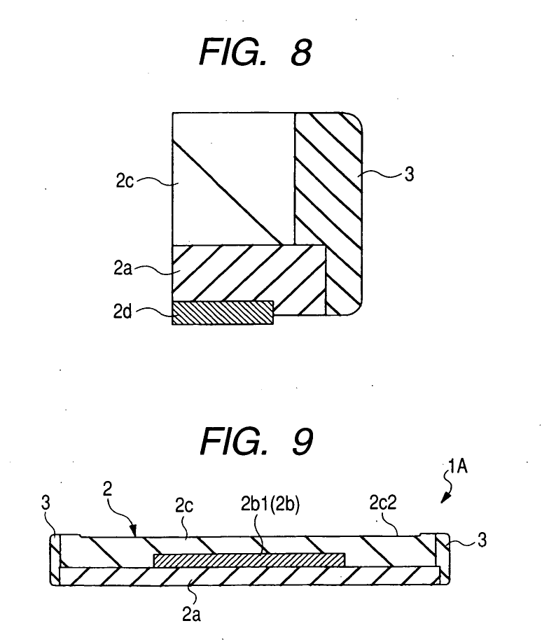

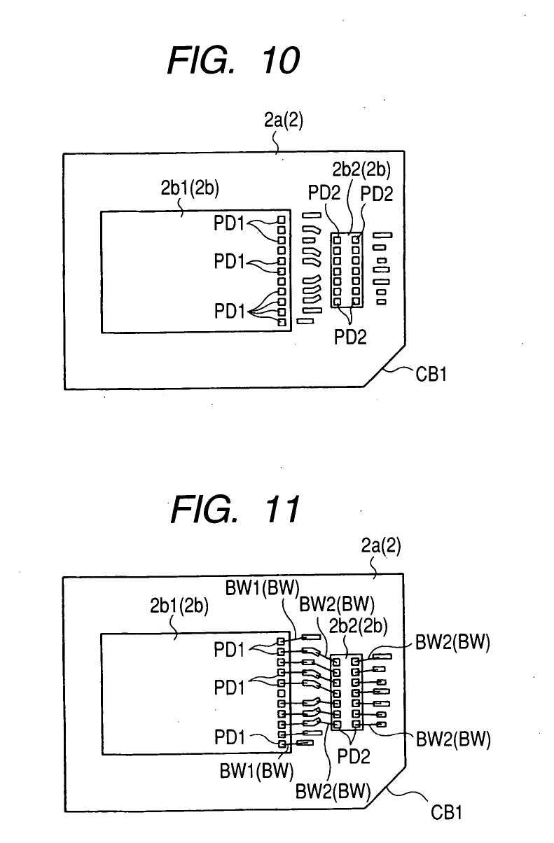

FIG. 1 is an overall plan view of a main surface of a memory card 1A according to the present embodiment, FIG. 2 is an overall plan view of a back face of the memory card 1A shown in FIG. 1, FIG. 3 is a front view of the memory card 1A seen from the direction shown by an arrow A in FIGS. 1 and 2, FIG. 4 is a rear view of the memory card 1A seen from the direction shown by an arrow B in FIGS. 1 and 2, FIG. 5 is a side view of the memory card seen 1A from the direction shown by an arrow C in FIGS. 1 and 2, FIG. 6 is a side view of the memory card 1A seen from the direction shown by an arrow D in FIGS. 1 and 2, FIG. 7 is a sectional view taken along a line X1-X1 in FIG. 1, FIG. 8 is an enlarged sectional view of an area AR in FIG. 7, FIG. 9 is a sectional view taken along a line Y1-Y1 in FIG. 1, FIG. 10 is an overall plan view of a main surface of a wiring board 2a of a memory body 2 composing the memory card 1A shown in FIG. 1, and FIG. 11 is an overall plan view of the main surface of the wiring board 2a shown in FIG. 10 to which a bonding wire BW is added.

The memory card (IC card) in the embodiment 1 is usable as an auxiliary memory device of various portable electronic devices, such as information processing device of a portable computer or the like, an image processing device of a digital camera or the like, a communication device of a cellular phone or the like.

This memory card 1A is made of a small thin plate of a rectangular shape having a great chamfered section CA1 for an index at one corner, for example. It has, for example, a contour dimension of a width W1 of 24 mm, a length L1 of 32 mm and thickness D1 of 1.4 mm. This memory card 1A is a card having the same appearance standard and the same function as those of a so-called full-size multi media card. It has a memory body (card body) 2 and a frame-like buffer section (first resin section) 3 that is bonded so as to cover the outer periphery face (the face crossing the main surface and the back surface of the memory card and including the outer peripheral front face, outer peripheral both side faces and outer peripheral back face) of the memory body 2.

The memory body 2 has a wiring board 2a, semiconductor chips (hereinafter simply referred to as chips) 2b (2b1, 2b2) mounted on the main surface of the wiring board 2a and a sealing section (second resin section) 2c for sealing the chips 2b. The wiring board 2a of the memory body 2 has a structure wherein one metal wiring layer (wiring) or multiple metal wiring layers (wiring) of two or more layers, for example, are formed in an insulating member such as a glass epoxy resin or the like. The wiring on the main surface (first face, chip-mounting face) of the wiring board 2a is electrically connected to plural external terminals 2d on the back face (second face at the back side of the first face) of the wiring board 2a via a through-hole. The external terminals 2d are brought into contact with connector terminals of the electronic device to establish an electrical connection between the memory card 1A and the electronic device. FIG. 2 shows the case wherein, for example, seven external terminals 2d are arranged side by side along the short-side direction (widthwise direction) of the wiring board 2a. In addition to this, there are various terminal arrangements including the one wherein, for example, thirteen external terminals 2d are arranged side by side in two rows along the short-side direction of the wiring board 2a.

This wiring board 2a is formed to have a planar appearance of, for example, a rectangular shape. A chamfered section CB1 is formed at one corner (corresponding to the aforesaid chamfered section CA1 for an index). Mounted on the main surface of the wiring board 2a are two chips 2b1 and 2b2, each having a different plane dimension, with each main surface (device-forming face) facing upward and each back face bonded to the wiring board 2a by a bonding agent. These two chips 2b1 and 2b2 are arranged side by side along the longitudinal direction of the wiring board 2a.

The chip 2b1 having relatively large plane dimension has formed thereon a flash memory having a memory capacity of, for example, 16 M bytes (128 M bytes), 32 M bytes (256 M bits) or 64 M bytes (512 M bits). Plural memory chips 2b1 may be arranged on the main surface of the wiring board 2a to obtain a desired memory capacity as a whole. Further, chips 2b1 are laminated in the direction crossing the main surface of the wiring board 2a to obtain a desired memory capacity as a whole. Laminating chips 2b1 as described above enables to secure a great capacity with a small occupied area. Plural bonding pads (hereinafter referred to as pads) PD1 are arranged on the main surface of the memory chip 2b1 in the vicinity of its one side along this one side. Pads PD1 are electrically connected to the wiring on the main surface of the wiring board 2a through bonding wires (hereinafter simply referred to as wire) BW1 (BW). Each bonding wire BW1 is made of a gold wire such as, for example, gold (Au) or the like.

On the other hand, a controller for controlling the operation of the flash memory circuit on the chip 2b1 is formed on the chip 2b2 having relatively a small plane dimension. On the main surface of the controller chip 2b2, plural pads PD2 are respectively arranged in a row in the vicinity of opposite two long sides along these long sides. The pads PD2 are electrically connected to the wiring on the main surface of the wiring board 2a through wires BW2. Each wire BW2 is made of a gold wire such as, for example, gold (Au) or the like.

Further, a sealing section 2c is formed on the main surface (first face) of the wiring board 2a so as to cover the chips 2b1, 2b2, wires BW1 and BW2. The sealing section 2c is made of a thermosetting resin such as, for example, orthocresol novolac epoxy resin or biphenyl epoxy resin. One great object of the sealing section 2c is to satisfactorily seal the chip 2b and wire BW. This sealing section 2c includes therein plural fine fillers (its average particle size is about 50 μm, for example) made of a quartz glass material such as, for example, silicon dioxide (SiO2), that is harder than a resin, for enhancing mechanical strength, reduced hygroscopicity and moldability and adjusting (reducing) thermal expansion coefficient. The content ratio of fillers in the sealing section 2c is, for example, about 60 wt % to 80 wt %. Besides, the sealing section 2c includes accelerating agent (catalyst for promoting the reaction of resin), release agent, flame retardant, coloring agent or the like. Carbon particles are used as the coloring agent. Therefore, the sealing section 2c is made into a black color. The reason for making the sealing section 2c black is to prevent the irradiation of ultraviolet ray to the chip 2b or to easily find the sealing resin left in a die, since there may be the case where the memory state is changed (soft error) when the ultraviolet ray at the outside of the memory card 1A is irradiated to the chip 2b1.

Since the resin of the sealing section 2c comes in direct contact with the chips 2b or wires BW, high and elaborate controllability and material adjustment (selection) are necessary upon forming the sealing section 2c (at the mold process). For example, there may be the case where the wires BW fall down to cause a short-circuit when the resin injection speed is fast, since the each wire BW is extremely thin. Further, a void may occur at the sealing section 2c when there is a problem in the resin injection speed and resin viscosity. Therefore, a so-called transfer molding method is used for molding the sealing section 2c, wherein a thermosetting resin made into a tablet is melted in a heating chamber (pod) of a die and filled in a cavity of the die by plunger pressure to mold the sealing section 2c. By using this transfer molding method, the chips 2b and wires BW are satisfactorily sealed without causing the foregoing problem.

The memory card 1A of this embodiment 1 does not use a so-called cap, so that the thickness of the memory card 1A is equal to the thickness of the buffer section 3 and the top face of the sealing section 2c is exposed to the outside. Specifically, a part of the appearance of the memory card 1A is formed by the sealing section 2c. A thickness of an MMC having a cap is composed of four factors, i.e., the thickness of a mold resin, thickness of the wiring board, thickness of a cap and thickness of a bonding agent, whereby it is difficult to adjust the variation provision, thereby entailing a problem of being difficult in the management of manufacture. Further, the thickness of the MMC is defined by a standard value, but the thickness of the cap, thickness of the bonding agent and thickness of the wiring board are reduced to reach the limit thickness, with the result that it is difficult to further increase the thickness of the mold resin. Specifically, it is difficult to increase the memory capacity by increasing the laminated number of chips. On the other hand, the thickness of the memory card 1A can be composed of two factors, i.e., the thickness of the sealing section 2c and the thickness of the wiring board 2a, whereby the adjustment of the variation provision of each factor is facilitated, thereby facilitating the management of manufacture. Moreover, the thickness that is allowed for the sealing section 2c can be increased by the reduced amount of the thickness of the cap and the thickness of the bonding agent used for bonding the cap to the sealing section, with the result that the laminated number of chips 2b can be increased, and hence, the memory card 1A can cope with the further increase in the memory capacity. Further, the cap is unnecessary, so that it is free from deficiency such as a break of a cap, thereby being capable of enhancing yield and reliability of the memory card 1A. It should be noted that a triangular shallow recess 2c1 at the front face of the memory card 1A is a mark for indicating the inserting direction of the memory card 1A. Further, a shallow recess 2c2 over a wide range of the top face of the sealing section 2c is for forming an area on which a seal recording thereon information of the memory card 1A is adhered. A groove 2c3 at the top face of the sealing section 2c at the back face of the memory card 1A is a groove for assisting to draw the memory card 1A from the electronic device.

The buffer section 3 is provided at the outer peripheral face (face crossing the main face and back face of the memory card and including the outer peripheral front face, outer peripheral both side faces and outer peripheral rear face) so as to border the outer peripheral face of the memory body 2. Specifically, the outer peripheral face (front face, both side faces and rear face) of the sealing section 2c and the wiring board 2a is covered by the buffer section 3 so as not to be exposed to the outside. The inner peripheral face of the buffer section 3 is directly bonded to the side face of the sealing section 2c and the main face and the side face of the wiring board 2a without a bonding agent, wherein the step formed at its inner peripheral face is fitly in place at the step formed by the side face of the sealing section 2c and the main face of the wiring board 2a. Thus, the buffer section 3 is fixedly bonded to the sealing section 2c and the wiring board 2a so as not to easily be released.

This buffer section 3 is made of a thermoplastic resin such as, for example, modified polyphenylene ether resin or polyamide MXD6 (trademark of Mitsubishi Engineering Plastics Co.). This buffer section 3 includes plural fillers, different from the fillers in the sealing section 2c, such as, for example, glass fiber or calcium carbonate, for enhancing resin strength and reducing cost. The content ratio of the fillers in the buffer section 3 is set so as to be less than the content ratio of the fillers in the sealing section 2c, and it is, for example, approximately 10% to 30% of the whole resin for forming the buffer section 3. The particle size or dimension of each filler (fiber or powder) included in the buffer section 3 is smaller than the particle size or dimension of the filler included in the sealing section 2c. It is approximately several μm. Moreover, the buffer section 3 may not include fillers.

Therefore, the buffer section 3 is softer than the sealing section 2c. The bending elastic modulus of the sealing section 2c and the buffer section 3 changes depending upon the environment (temperature or humidity) or test condition, so that there is no concrete number fir hardness, but under ISO 178 (test method), for example, the hardness of the sealing section 2c is about 26,970 Mp and the hardness of the buffer section 3 is about 16,500 Mpa or 2,470 Mpa, which means that the bending elastic modulus of the buffer section 3 is lower than that of the sealing section 2c.

Moreover, the surface of the buffer section 3 is smoother than the surface of the sealing section 2c. The reason is as follows. The particle size or the dimension of the fillers included in the sealing section 2c is greater than that of the fillers in the buffer section 3, and the fillers included in the sealing section 2c are greatly exposed to the surface as described above, whereby the surface of the sealing section 2c is rough (in this case, the height from the bottom to top of microprojecting section on the surface of the sealing section 2c is greater than the height from the bottom to top of microprojecting section on the surface of the buffer section 3). On the other hand, the particle size or the dimension of the fillers included in the buffer section 3 are smaller than those of the fillers in the sealing section 2c, and the fillers included in the buffer section 3 are hardly exposed to the surface as described above, whereby the surface of the buffer section 3 is smooth. Therefore, the friction coefficient of the buffer section 3 to the connector is smaller than that of the sealing section 2c to the connector.

Further, a round taper having a size determined by the standard is formed at each corner (corner formed at the section where faces different from each other cross over) at the outer periphery of the buffer section 3 in order to relieve a shock when other members such as connector pins or guide rail is brought into contact with the corner.

According to these, the embodiment 1 can reduce or prevent that the connector terminal or guide rail is deteriorated or damaged due to contact with the memory card 1A, when the memory card 1A is inserted into the connector of the electronic device.

Since the buffer section 3 does not come in direct contact with the chips 2b or wires BW, a high elaborate controllability or material adjustment (selection) is not as much required upon molding the buffer section 3 as molding the sealing section 2c. Therefore, the buffer section 3 is formed by a so-called plastic injection molding. Specifically, the buffer section 3 is formed such that a powdery plastic resin (thermoplastic resin) is heated to be in a fluid state, filled in a cavity of a closed die in several seconds, and then, solidified in the die. As for the sealing section 2c, adhesion of the resin to the die is strong, so that it is unsuitable to form concave/convex having a complicated shape on the surface of the sealing section 2c, considering the releasability. On the other hand, as for the buffer section 3 formed by plastic injection molding, it is possible to form concave/convex having a complicated shape on the surface of the buffer section 3 with high precision. It should be noted that a cutout section 3a of the buffer section 3 at the rear face of the memory card 1A is a section into which a resin is injected upon molding the sealing section 2c.

Further, although the buffer section 3 is made to be black, like the sealing section 2c, the buffer section 3 is not so much required to be black, as stated in the explanation of the sealing section 2c, so that the buffer section 3 may have a chromatic color having a color wavelength between purple and red such as, for example, purple, blue, green, yellow, red or the like, may have an achromatic color such as white or gray except for black, may have gold, silver or sepia, or may be transparent. Thus, the color of the buffer section 3 can be changed according to various demands, i.e., the color of the buffer section 3 can be changed depending upon the difference in memory capacity of the memory card 1A or according to a demand by a customer, thereby being capable of enhancing discriminating ability and authentication ability. Accordingly, the management of the memory card 1A and the facility in selection of the memory card 1A can be enhanced. Specifically, it is possible to provide a discriminating ability and authentication ability to the buffer section 3, in addition to the buffer function to the connector. Varying the color of the buffer section 3 can produce aesthetic quality through the sense of sight. Specifically, it is possible to provide an aesthetic function to the buffer section 3.

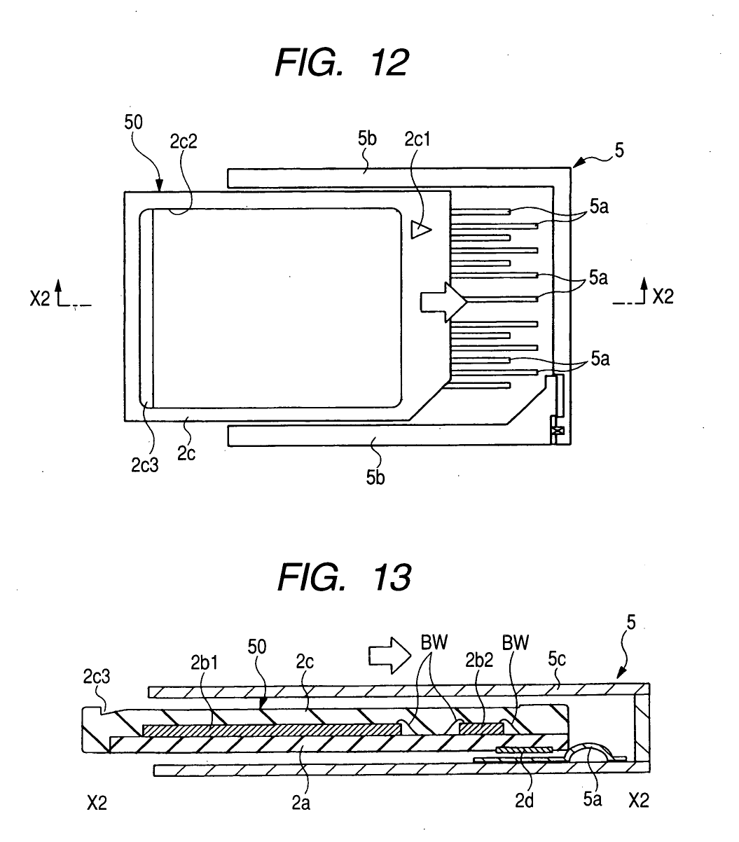

Subsequently, a subject in the case where the memory card studied by the present inventors is inserted into an electronic device will be explained with reference to FIGS. 12 and 13.

FIG. 12 is a plan view of a memory card 50 that is inserted into a connector and FIG. 13 is a sectional view taken along a line X2-X2. The appearance of the memory card 50 is composed of a wiring board 2a and a sealing section 2c. This memory card 50 has neither a cap nor a buffer section 3. Although the illustrated case is that the corner of the wiring board 2a is exposed at the lower section of the front face of the memory card 50, a part of the sealing section 2c may be provided at the same section. In either case, when the memory card 50 is inserted into the connector 5, the lower section of the front face of the memory card 50 is at first brought into contact with connector pins 5a of the connector 5. Since the corner at the lower section of the front face of the memory card 50 is not sufficiently chamfered, and hence, is angular, or it is harder than the cap (in the case where there is the sealing section 2c at the lower section of the front face of the memory card 50, the surface is rougher than the cap due to the presence of fillers), there is a fear that the deterioration or damage occurs on the connector pins 5a, examples of which include that gold plating such as gold (Au) or nickel (Ni) on each surface of the connector pins 5a is scraped off or the connector pins 5a are broken. Currently, there is a tendency that the number of the external terminals 2d is increased and the width of the external terminal 2d is reduced with high functionalization of the MMC, so that the width of each connector pin 5a that is brought into contact with each external terminal 2d is more and more reduced such as from about 1 mm to about 0.6 mm, with the result that the mechanical strength may be difficult to secure. Therefore, the aforesaid fear becomes a matter to be considered. Further, when the side face (the surface of the sealing section 2c) of the memory card 50 is brought into contact with the guide rail 5b of the connector 5, the guide rail 5 may be scraped off or there is a fear that foreign matter are produced due to the scrape of the guide rail, since the surface of the sealing section 2c is rougher than the cap. Alternately, when the memory card 50 is pushed upward by the urging force of the connector pins 5a made of a plate spring, the upper corner at the front face of the memory card 50 is brought into contact with a metallic upper shell 5c of the connector 5, possibly causing the upper shell 5c to be damaged due to the reason same as the foregoing reason.

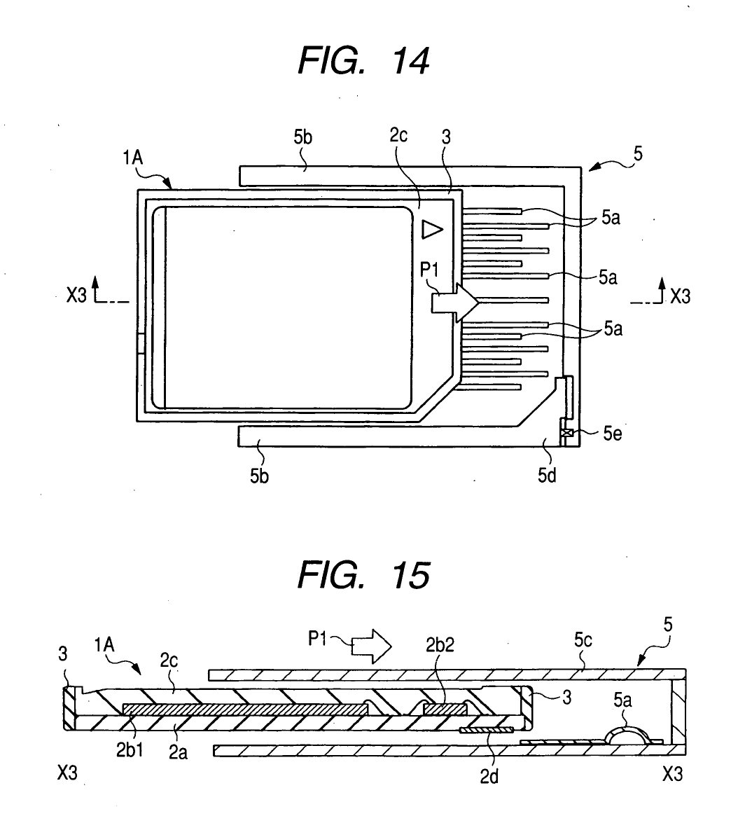

Subsequently, the state where the memory card 1A according to the embodiment 1 is inserted into an electronic device will be explained with reference to FIGS. 14 to 18.

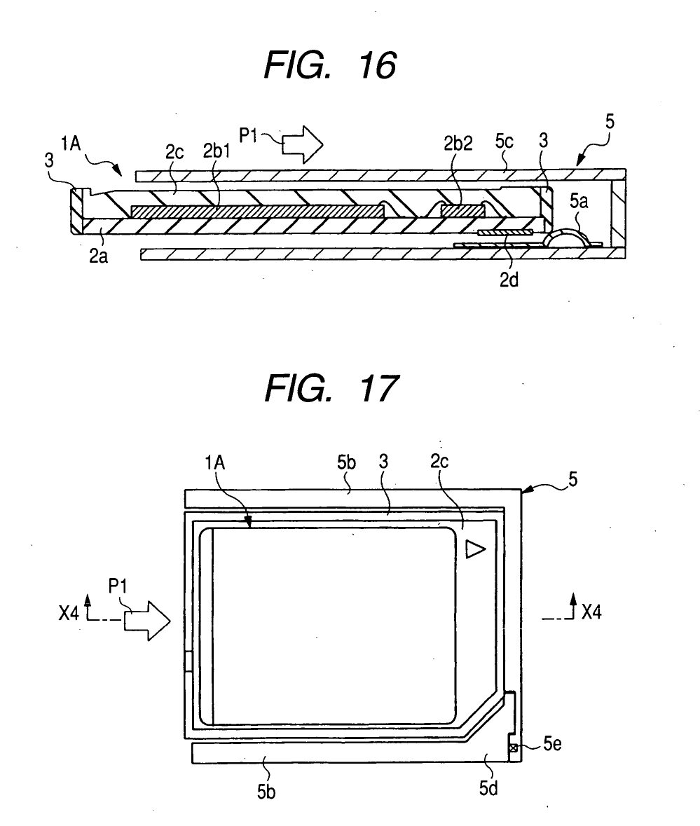

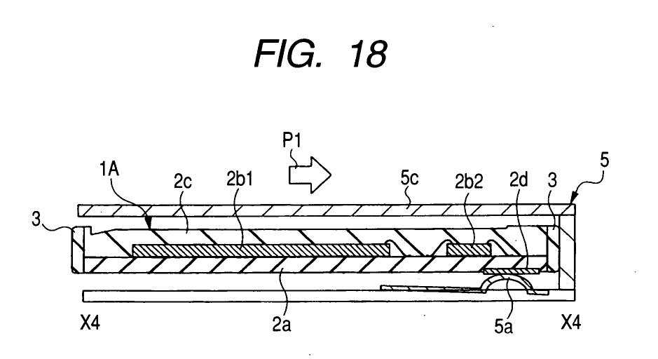

FIG. 14 is a plan view of the memory card 1A before it is mounted to a connector, FIG. 15 is a sectional view taken along a line X3-X3 in FIG. 14, FIG. 16 is a sectional view of the memory card 1A that is further pushed from the state shown in FIG. 15 until the lower section of the front face of the memory card 1A is brought into contact with the connector pins 5a, FIG. 17 is a plan view of the memory card 1A that is fully inserted into the connector 5, and FIG. 18 is a sectional view taken along a line X4-X4 in FIG. 17.

In this embodiment 1, when the memory card 1A is inserted in the direction shown by an arrow P1 in FIGS. 14 and 15, the lower section of the buffer section 3 at the front face of the outer periphery of the memory card 1A is brought into contact with the connector pins 5a. The round taper is formed at the outer peripheral corner of the buffer section 3 as described above, and further, the buffer section 3 is softer than the sealing section 2c and wiring board 2a and the surface of the buffer section 3 is smoother than the surface of the sealing section 2c or the wiring board 2a, so that the shock generated when the buffer section 3 is brought into contact with the connector pins 5a can be relieved. Further, even if the buffer section 3 is brought into contact with the connector pins 5a, the buffer section 3 does not scrape off the connector pins 5a. Accordingly, disadvantages can be reduced or prevented such as cases wherein the metal plating on each connector pin 5a is scraped off or the connector pins 5a themselves are broken when the memory card 1A is mounted to the electronic device. Further, since the buffer section 3 having a smooth surface is brought into contact with the guide rail 5b of the connector 5 upon inserting or drawing the memory card 1A in the embodiment 1, disadvantages can be reduced or prevented such as cases wherein the guide rail 5b is scraped off or foreign matter are produced with the scrape of the guide rail 5b. Moreover, even if the upper corner at the front face of the memory card 1A is brought into contact with the upper shell 5c of the connector 5 when the memory card 1A is pushed upward by the urging force of the connector pins 5a, a disadvantage of giving a damage to the upper shell 5c can be reduced or prevented in the embodiment 1, since the buffer section 3 is also present at the upper corner of the front face of the memory card 1A.

Subsequently, when the memory card 1A is further inserted as shown in FIGS. 17 and 18, the external terminals 2d of the memory card 1A are electrically connected to the connector pins 5a as being brought into contact with each other. Each of the connector pin 5a is formed of a plate spring as stated above, and further, the memory card 1A is urged downward by an elastic pawl integrally molded with the upper shell 5e of the connector 5. According to this, the external terminals 2d of the memory card 1A are firmly brought into contact with the tip end of each connector pin 5a. When the memory card 1A is inserted into the connector 5, a slider 5d of the connector 5 is slid in the direction of P1 to be fixed by the memory card 1A. In order to remove the memory card 1A from the connector 5, the rear face of the memory card 1A that is inserted into the connector 5 is lightly pushed toward the direction of P1. As a result, the fixed state is released, and the memory card 1A slightly pops out backward, whereby the memory card 1A can easily be drawn from the connector 5 (push-push system). In this case too, the memory card 1A can smoothly be drawn since the surface of the buffer section 3 is smooth. Further, it is unnecessary to extremely increase the spring force for draw, whereby there is no fear that the memory card 1A is greatly popped out upon drawing the memory card 1A.

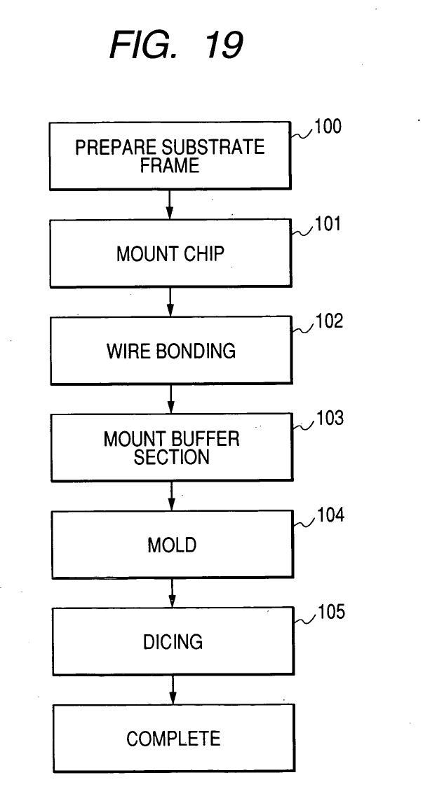

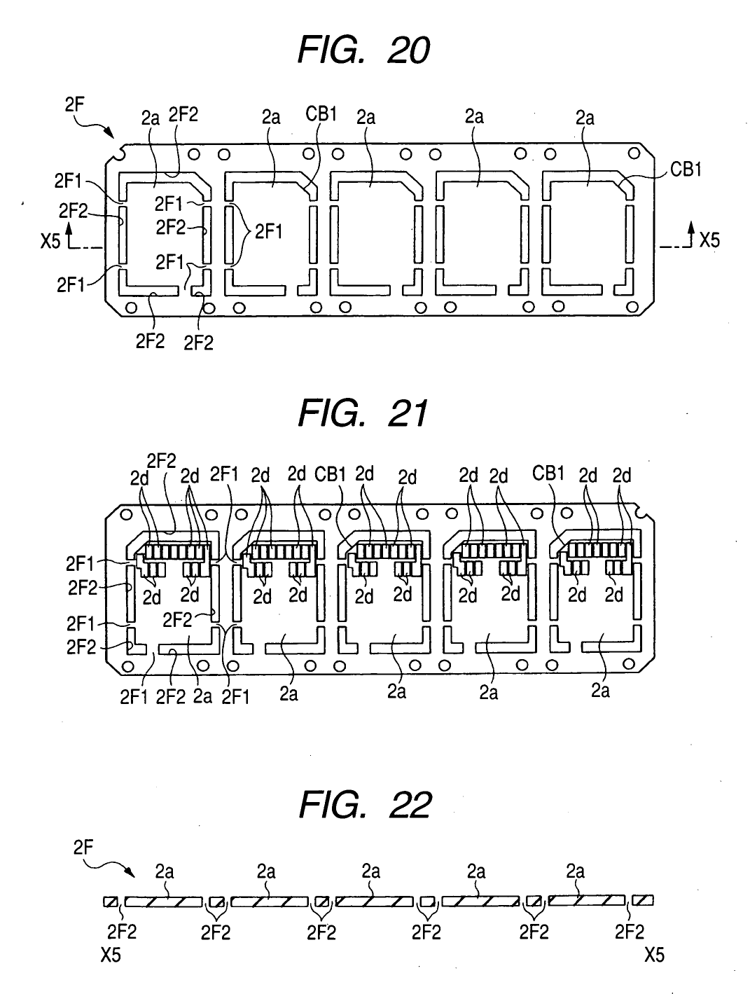

Subsequently, one example of a manufacturing method of the memory card 1A according to the embodiment 1 will be explained with reference to FIGS. 20 to 35 along a manufacturing flowchart shown in FIG. 19.

Firstly, a board frame 2F shown in FIGS. 20 to 22 is prepared (step 100 in FIG. 19). FIG. 20 is an overall plan view of a main surface (first face) of the board frame 2F, FIG. 21 is an overall plan view of a back face (second face) of the board frame 2F of FIG. 20 and FIG. 22 is a sectional view taken along a line X5-X5 in FIG. 20. The board frame 2F is a mother board for a wiring board having plural wiring boards 2a so as to be integral. Each wiring board 2a is connected and supported by the board frame 2F through a lifting section 2F1. The illustrated case is the wiring board 2a having thirteen external terminals 2d. Further, numeral 2F2 denotes an opening section penetrating the main back face of the board frame 2F.

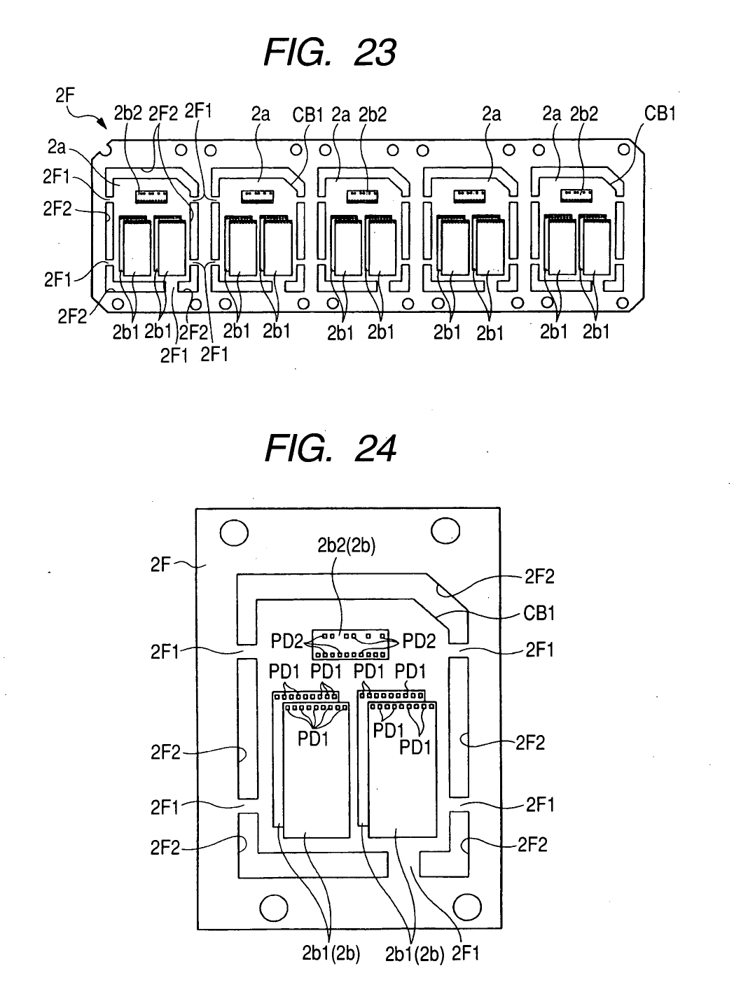

Subsequently, chips 2b1 and 2b2 are mounted (step 101 in FIG. 19) on the main surface of each wiring board 2a of the board frame 2F as shown in FIGS. 23 and 24. FIG. 23 is an overall plan view of the main surface of the board frame 2F after the chips 2b1 and 2b2 are mounted and FIG. 24 is an enlarged plan view of a unit section (one wiring board 2a) of the board frame 2F of FIG. 23. The illustrated case here is that two sets of two memory chips 2b1 that are laminated in the direction orthogonal to the main surface of the wiring board 2a, that is, four memory chips 2b1 in total, are mounted on the main surface of each wiring board 2a of the board frame 2F.

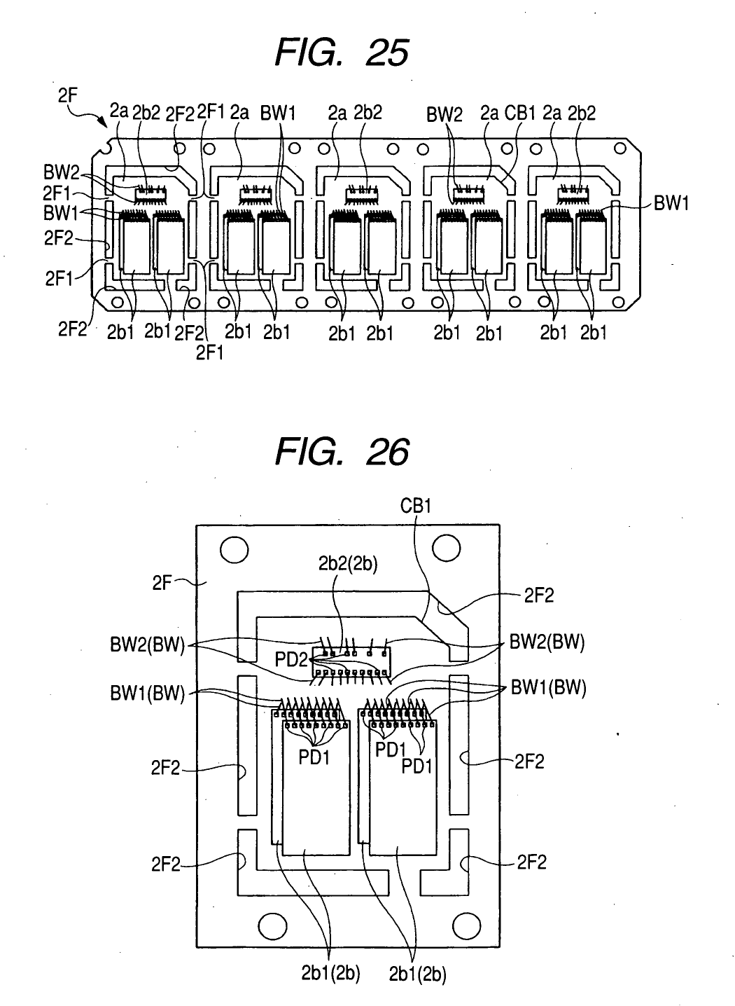

Then, pads PD1 and PD2 of the chips 2b1 and 2b2 on the main surface of each wiring board 2a of the board frame 2F and wiring (electrode) on the main surface of the wiring board 2a are electrically connected by wires BW1 and BW2 (step 102 in FIG. 19) as shown in FIGS. 25 and 26. FIG. 25 is an overall plan view of the main surface of the board frame 2F after the wire bonding process and FIG. 26 is an enlarged plan view of the unit section of the board frame 2F in FIG. 25.

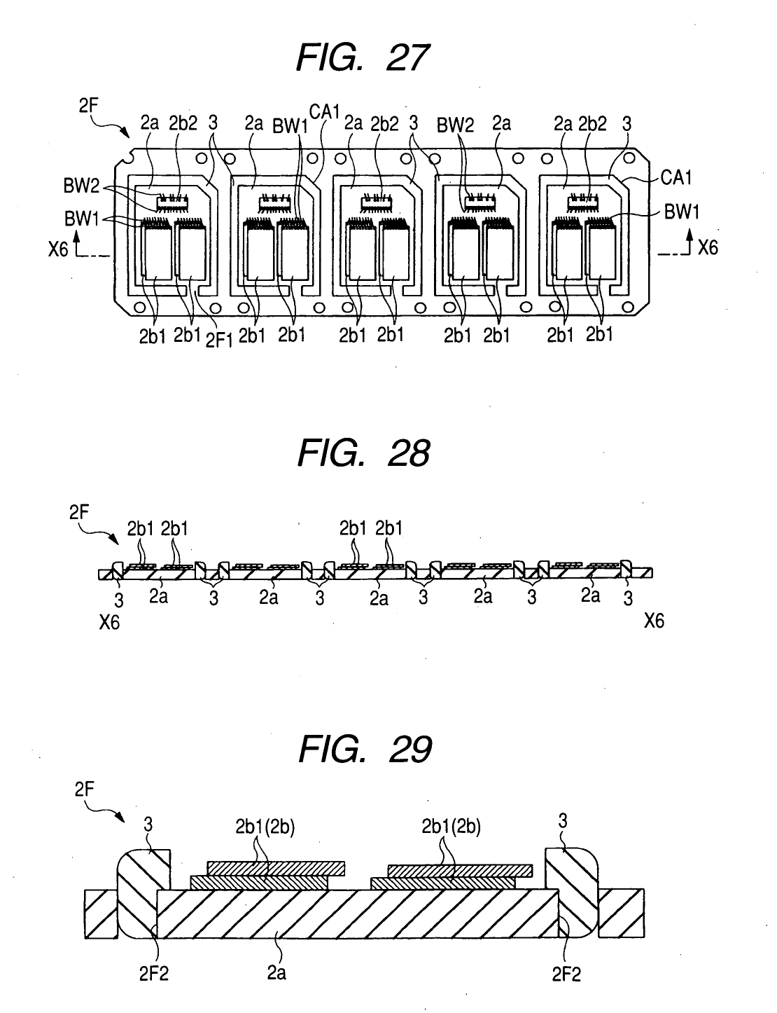

Subsequently, the buffer section 3 is mounted at the outer periphery of each wiring board 2a of the board frame 2F (step 103 in FIG. 19) as shown in FIGS. 27 to 29. FIG. 27 is an overall plan view of the main surface of the board frame 2F after the buffer section 3 is mounted, FIG. 28 is a sectional view taken along a line X6-X6 in FIG. 27 and FIG. 29 is an enlarged sectional view of the unit section of the board frame 2F in FIG. 28. The buffer section 3 is mounted to the board frame 2F with its lower section fitted into the opening section 2F2 of the board frame 2F. The buffer section 3 is made by a plastic injection molding as stated above. A round taper having a size defined by the standard has already been formed at the outer peripheral corner of the buffer section 3 at the plastic injection molding.

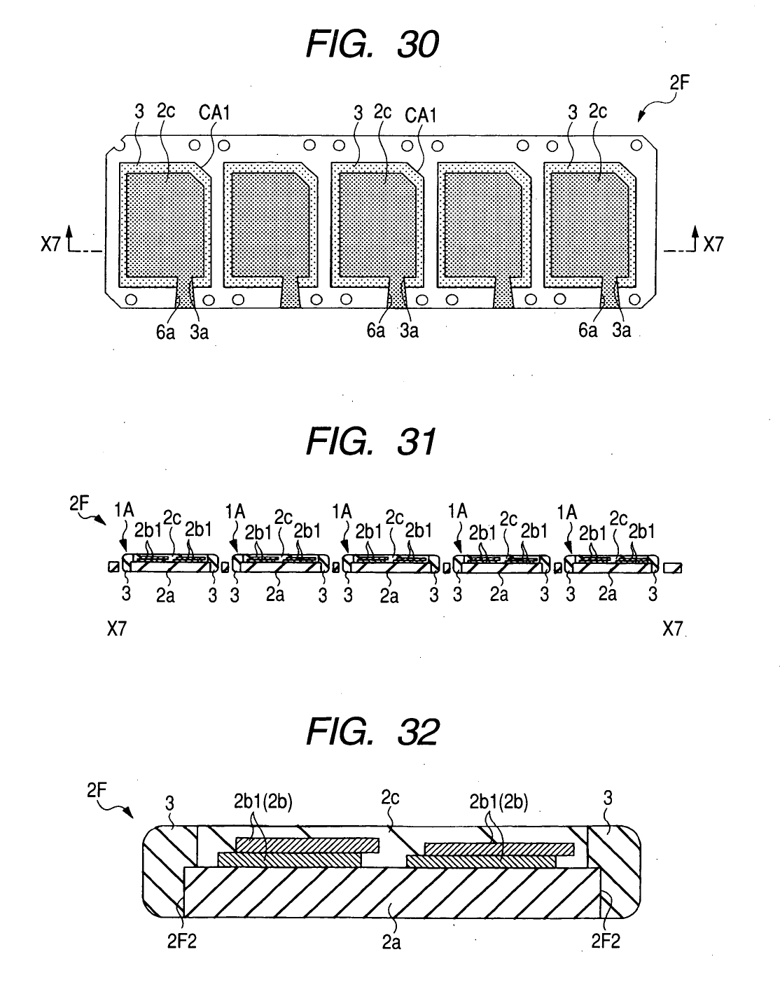

Then, the board frame 2F is transported to a die, whereupon the chips 2b1, 2b2 and wires BW on plural wiring boards 2a of the board frame 2F are sealed en block by a transfer molding (step 104 in FIG. 19) as shown in FIGS. 30 to 32. FIG. 30 is an overall plan view of the board frame 2F after this mold process, FIG. 31 is a sectional view taken along a line X7-X7 in FIG. 30 and FIG. 32 is an enlarged sectional view of the unit section of the board frame 2F in FIG. 31. The sealing section 2c is formed such that a thermosetting resin made into a tablet is melted in a heating chamber (pod) of the die and filled in the buffer section 3 and a cavity of the die by plunger pressure through a gate section 6a and the cutout 3a of the buffer section 3. The side face of the sealing section 2c is bonded as brought into direct contact with the inner peripheral face of the buffer section 3. Consequently, the sealing section 2c and the frame section 3 are more firmly bonded. The sealing section 2c is formed such that its top face agrees with the top face of the buffer section 3. In this manner, plural memory cards 1A are formed on the board frame 2F.

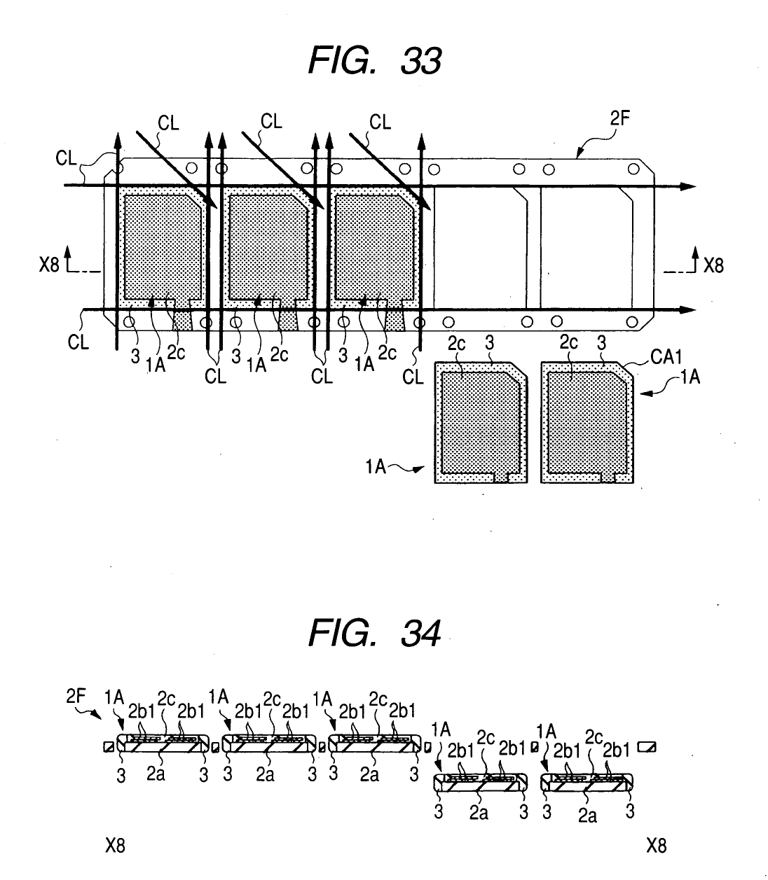

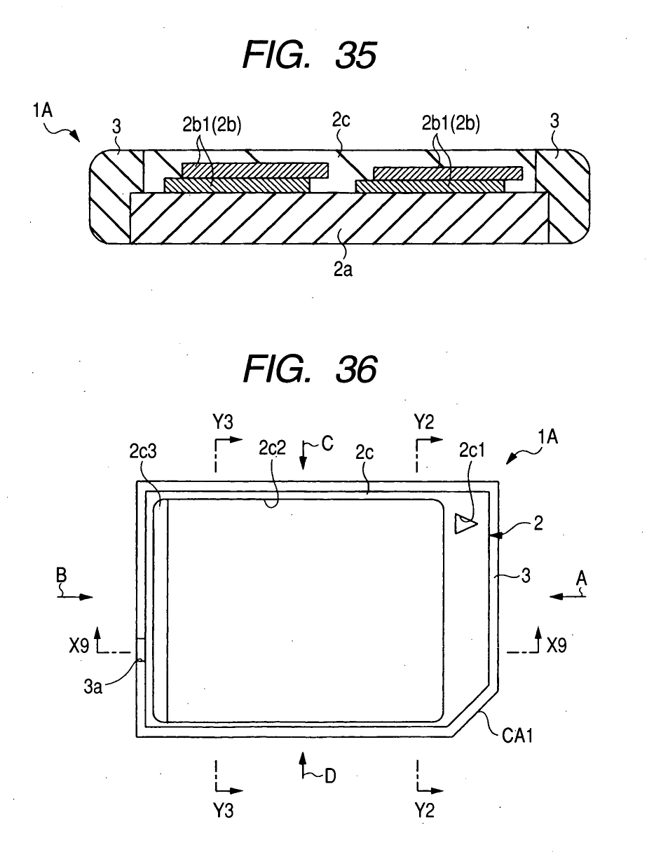

Then, the board frame 2F is cut by a dicing saw or waterjet cutter, whereby the individual memory card 1A is taken out from the board frame 2F (step 105 in FIG. 19), as shown in FIGS. 33 to 35. FIG. 33 is an overall plan view of the board frame 2F during this dicing process, FIG. 34 is a sectional view taken along a line X8-X8 in FIG. 33 and FIG. 35 is an enlarged sectional view of the memory card 1A cut out from the board frame 2F in FIG. 34. The board frame 2F is cut along the outer periphery of the buffer section 3. The arrows of cutting lines CL represent a cutting direction. The dicing saw is for cutting a subject to be cut by an extremely thin peripheral cutting edge mounted at a leading edge of a high-speed rotating spindle, while the waterjet cutter is for cutting the subject to be cut by jetting filler-containing liquid (pure water or the like) with a high flow rate.

### Embodiment 2

The embodiment 2 describes about the configuration of a full-size MMC that is formed by using a wiring board, which is used for a so-called reduced size MMC (hereinafter referred to as RSMMC) having a size and weight half that the foregoing full-size MMC.

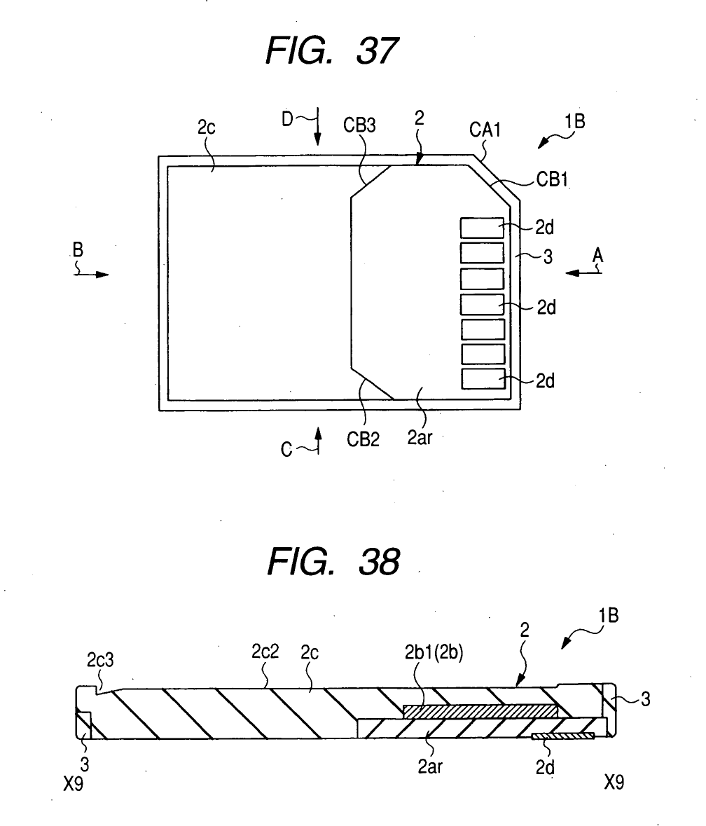

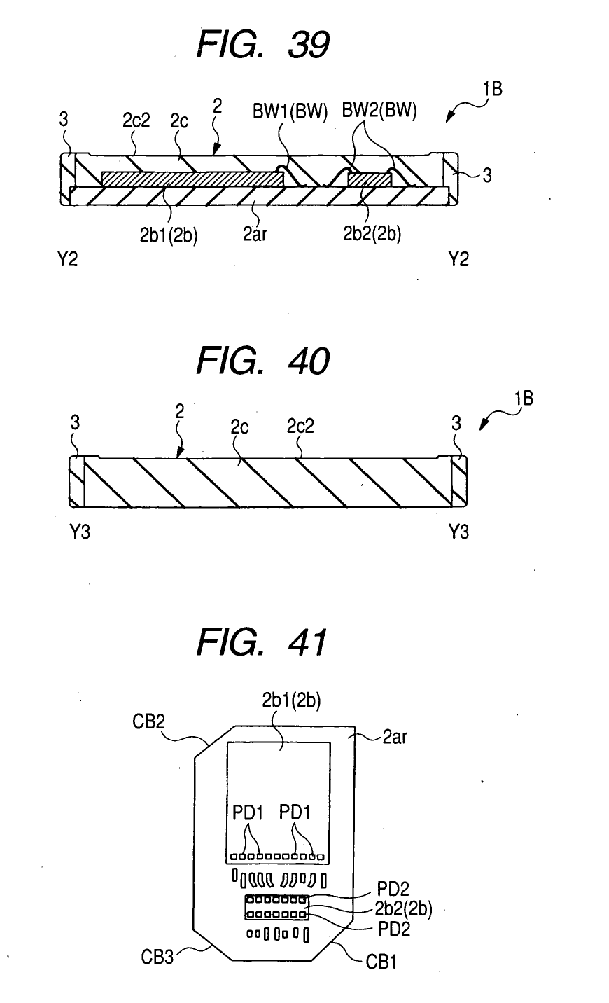

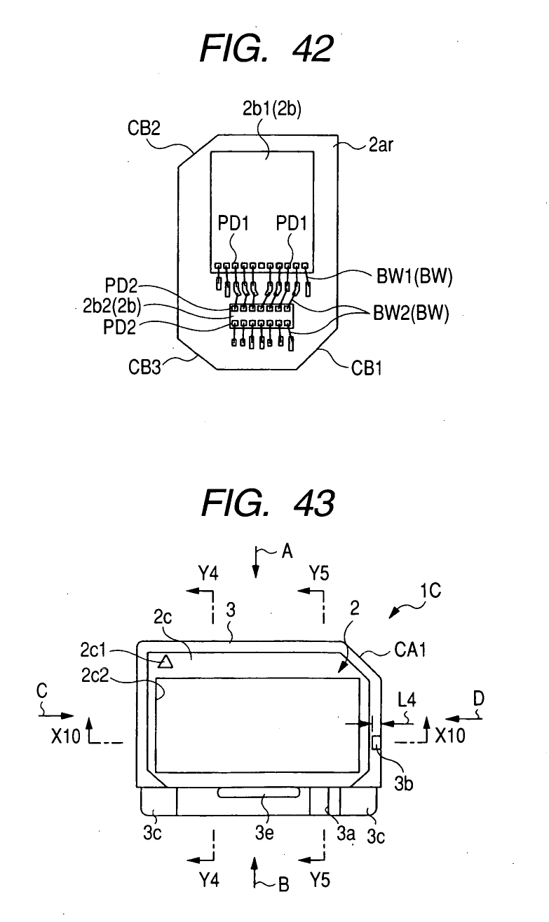

FIG. 36 is an overall plan view of a memory card 1B according to this embodiment, FIG. 37 is an overall plan view of a back face of the memory card 1B in FIG. 36, FIG. 38 is a sectional view taken along a line X9-X9 in FIG. 36, FIG. 39 is a sectional view taken along a line Y2-Y2 in FIG. 36, FIG. 40 is a sectional view taken along a line Y3-Y3 in FIG. 36, FIG. 41 is an overall plan view of a main surface of a wiring board 2ar composing the memory card 1B shown in FIG. 36 and FIG. 42 is an overall plan view of the main surface of the wiring board 2ar of FIG. 42 to which wires BW are added. The front view, rear view and side view of the memory card 1B according to the embodiment 2 are the same as FIGS. 3 to 6.

Although the memory card (IC card) 1B of this embodiment 2 is a full-size MMC, a wiring board for RSMMC is used for the wiring board 2ar. Specifically, the size of the wiring board 2ar in the longitudinal direction of the memory card 1B is about half the size of the memory card 1B in the longitudinal direction.

The planar outer appearance of the wiring board 2ar is formed into, for example, a rectangle. The wiring board 2ar has two great chamfered sections CB2 and CB3, in addition to a great chamfered section CB1 formed at the place corresponding to the chamfered section CA1 for an index. The chamfered sections CB2 and CB3 of the wiring board 2ar are originally formed in view of preventing a crack of a cap in an MMC having a cap or in view of reducing a weight of the wiring board 2ar. However, in the embodiment 2, providing the chamfered sections CB2 and CB3 at the wiring board 2ar can increase the contact area between the side face of the wiring board 2ar and the sealing section 2c, thereby making it possible to enhance the bond property between the sealing section 2c and the wiring board 2ar. The configurations other than these of the wiring board 2ar are the same as those of the wiring board 2a.

The chips 2b1 and 2b2 are arranged on the main surface of the wiring board 2ar along the longitudinal direction of the main surface (first face) of the wiring board 2ar. The relatively small chip 2b2 is arranged close to the chamfered section CB1 of the wiring board 2ar compared to the relatively great chip 2b1. The sealing section 2c is formed on the main surface of the wiring board 2ar so as to cover the chips 2b1, 2b2 and wires BW. The sealing section 2c is filled in the area of the memory card 1B other than the area on which the wiring board 2ar is arranged, thereby forming the outer appearance of the memory card 1B. Like the aforesaid embodiment 1, the buffer section 3 is provided at the outer peripheral face of the memory body 2 of the memory card 1B. This can reduce or prevent the deterioration or damage on the connector pins 5a or guide rail 5b of an electronic device to which the memory card 1B is to be mounted.

As described above, the embodiment 2 affords the following effects in addition to the effects obtained by the embodiment 1. Specifically, the wiring board 2ar for an RSMMC having a small area is used, with the result that cost for the memory card 1B can be decreased. Further, the weight of the memory card 1B can be reduced.

### Embodiment 3

The embodiment 3 describes about the configuration in case where the invention is applied to an RSMMC.

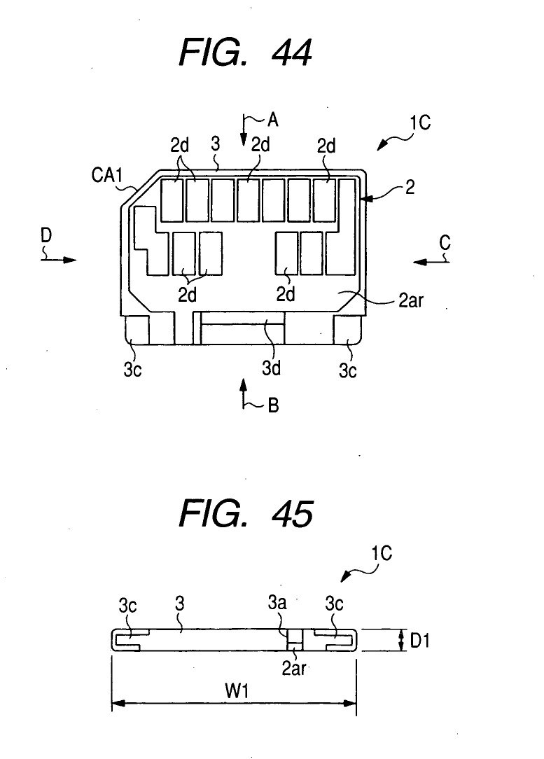

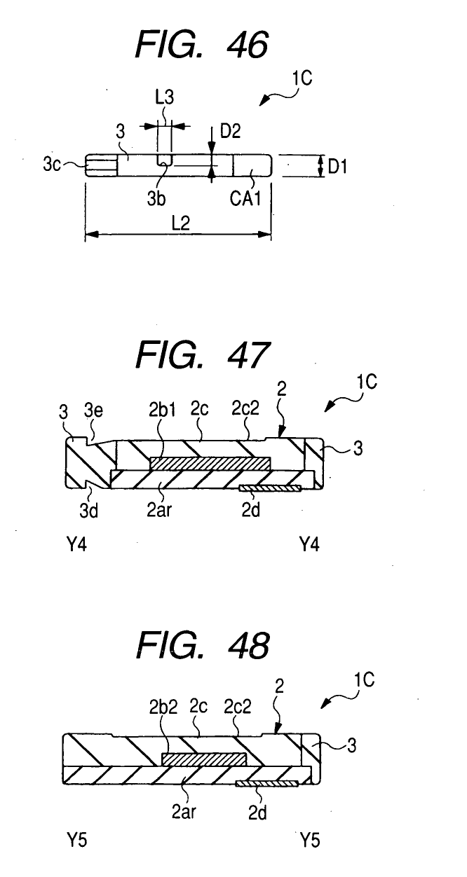

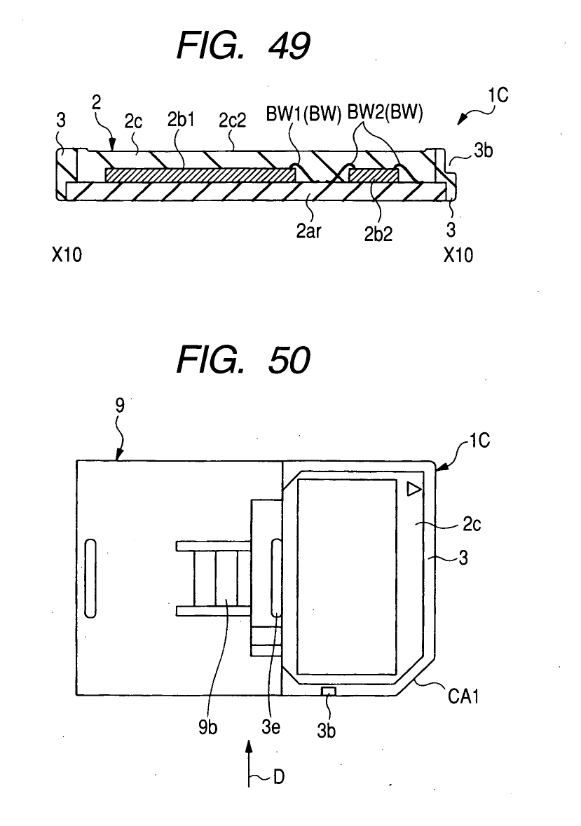

FIG. 43 is an overall plan view of a main surface of a memory card 1C according to this embodiment, FIG. 44 is an overall plan view of a back face of the memory card 1B shown in FIG. 43, FIG. 45 is a rear view of the memory card 1C seen from a direction of an arrow B in FIGS. 43 and 44, FIG. 46 is a side view of the memory card 1C seen from a direction of an arrow D in FIGS. 43 and 44, FIG. 47 is a sectional view taken along a line Y4-Y4 in FIG. 43, FIG. 48 is a sectional view taken along a line Y5-Y5 in FIG. 43 and FIG. 49 is a sectional view taken along a line X10-X10 in FIG. 43. The front view of the memory card 1C of this embodiment 3 is the same as FIG. 3.

This memory card (IC card) 1C has the same appearance standard and the same function as those of a so-called RSMMC. The contour dimension of the memory card 1C is, for example, about 24 mm in width W1, about 18 mm in length (first length) L2 and about 1.4 mm in thickness D1. The memory card 1C can be used as it is in a small-sized electronic device such as, for example, cellular phone or digital camera, but it can be used in a relatively large-sized electronic device such as a portable personal computer by mounting thereto an adaptor (auxiliary device) to make it a full-size MMC (hereinafter referred to as FSMMC).

The configuration of the wiring board 2ar composing the memory body 2 of the memory card 1C is the same as that explained in the embodiment 2. The arrangement of the chips 2b1 and 2b2 on the main surface of the wiring board 2ar is also the same as that shown in FIGS. 41 and 42 in the embodiment 2.

Like the embodiments 1 and 2, the buffer section 3 is formed at the outer peripheral face (outer peripheral front face, outer peripheral side faces and outer peripheral rear face) of the memory body 2 in this embodiment 3. In this embodiment 3, a recess 3b is formed at the buffer section 3 at a part of the short side where the chamfered section CA1 is formed. This recess 3b is for realizing a latch mechanism for holding the memory card 1C in the electronic device in order that the memory card 1C incorporated into the electronic device is not forcibly pulled out or in order that the memory card 1C is not popped out against the user's wish when the electronic device is dropped. The length L3 of the recess 3b is, for example, about 1.5±0.1 mm, and the length L4 is, for example, about 0.55±0.1 mm. Further, the recess 3b ends midway of the depth of the memory card 1C in the thickness direction, and a part of the buffer section 3 is left at its bottom section, the depth D2 of which is, for example, about 0.65±0.1 mm. The recess 3b can be formed at plural sections. In the RSMMC, the length L2 of the memory card 1C is shorter than the width W1 orthogonal to the length L2, so that the length of the guide rail 5b at the connector side to which the memory card 1C is to be mounted becomes shorter. Therefore, in the case of using a connector that presses the side face of the memory card 1C, the memory card 1C is liable to disconnect from the connector due to a rotational deviation (rotating direction in a plane parallel to the main surface of the memory card 1C). In this case, recess 3b may be formed at both opposite side faces of the buffer section 3. This can prevent the rotational deviation of the memory card 1C, thereby being capable of enhancing the ability to prevent the memory card 1C from falling off.

In the embodiment 3, the memory card 1C is provided at its rear face with an adaptor mounting section 3c, adaptor claw attaching groove 3d and a groove 3e at the buffer section 3. The adaptor mounting sections 3c, 3c have a convex cross section that are fitted into recesses of the adaptor for converting RSMMC into FSMMC. They are provided at both corners at the back of the memory card 1C. The adapter claw attaching groove 3d is a groove with which the adaptor claw is engaged. It is formed between the adaptor mounting sections 3c, 3c at both corners at the back surface of the memory card 1C. The groove 3e corresponds to the groove 2c3. It is a groove for assisting to take out the memory card 1C from the electronic device, and is formed between the adaptor mounting sections 3c, 3c at both corners on the main surface of the memory card 1C. The sealing section 2c formed by a transfer molding is unsuitable for forming a complicated shape or minute concave/convex thereon, considering the releasability, since adhesion of the resin to the die is strong. Specifically, it is difficult to form a complicated shape or minute concave/convex, such as the recess 3b, adaptor mounting sections 3c, adaptor claw attaching groove 3d and groove 3e, on the outer periphery of the MMC whose outer appearance is composed of the sealing section 2c, not using a cap. On the other hand, the buffer section 3 formed by a plastic injection molding has less necessity to consider the releaseability, and it is possible to form a complicated shape or minute concave/convex on the surface of the buffer section 3 with high precision, since the adhesion to the die is not so strong as the resin of the sealing section 2c. Specifically, it is possible to form a complicated shape or minute concave/convex, such as the recess 3b, adaptor mounting sections 3c, adaptor claw attaching groove 3d and groove 3e, on the memory card 1C according to the embodiment 3 with high precision. As described above, a role as a section for forming a microfabricating section can be provided to the buffer section 3, in addition to the buffer function to the connector, in the embodiment 3.

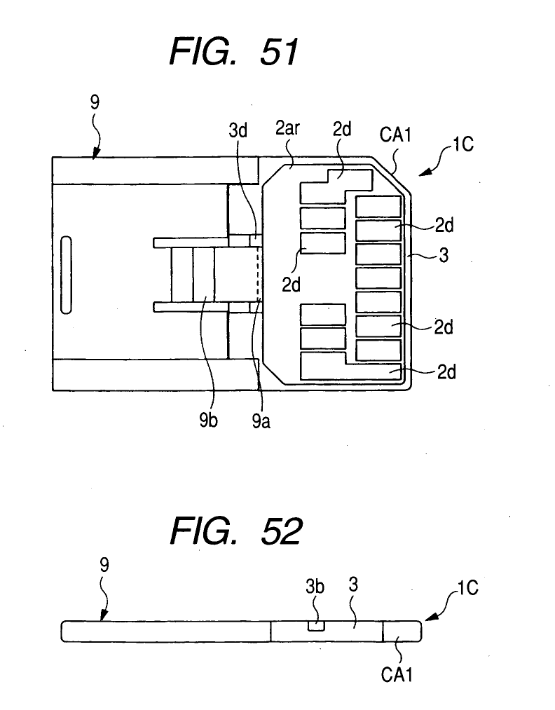

FIG. 50 is a plan view of a main surface of the memory card 1C to which the size-changing adaptor 9 is mounted, FIG. 51 is a plan view of the back face of the memory card 1C of FIG. 50 and FIG. 52 is a side view of the memory card 1C in FIG. 50 seen from the direction D.

The recess at the front face of the adaptor 9 is fitted into the convex adaptor mounting section 3c at the rear face of the memory card 1C, and the adaptor claw 9a of the adaptor 9 is fitted into the adaptor claw attaching groove 3d at the rear face of the memory card 1C, so that the adaptor 9 is detachably mounted to the rear face of the memory card 1C. The adaptor claw 9a is integrally connected to the adaptor 9 through a plate spring 9b. This adaptor claw 9a is latched to the adaptor claw attaching groove 3d as pressed against the memory card 1C by the urging force of the plate spring 9b, whereby the adaptor 9 is firmly fixed to the memory card 1C. By mounting the adaptor 9 to the memory card 1C as described above, the memory card 1C of the RSMMC size can be converted into the memory card 1C of the FSMMC size (for example, 24 mm ×32 mm ×1.4 mm). The recess 3b for preventing the memory card 1C from falling off is exposed at the side face of the converted memory card 1C, so that the converted memory card 1C can prevent that the memory card 1C is dropped off or popped out from the electronic device.

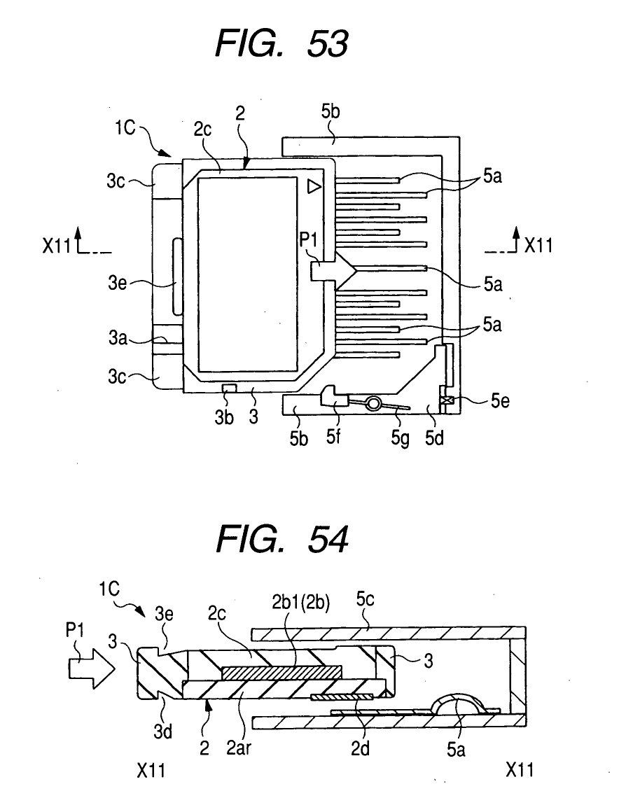

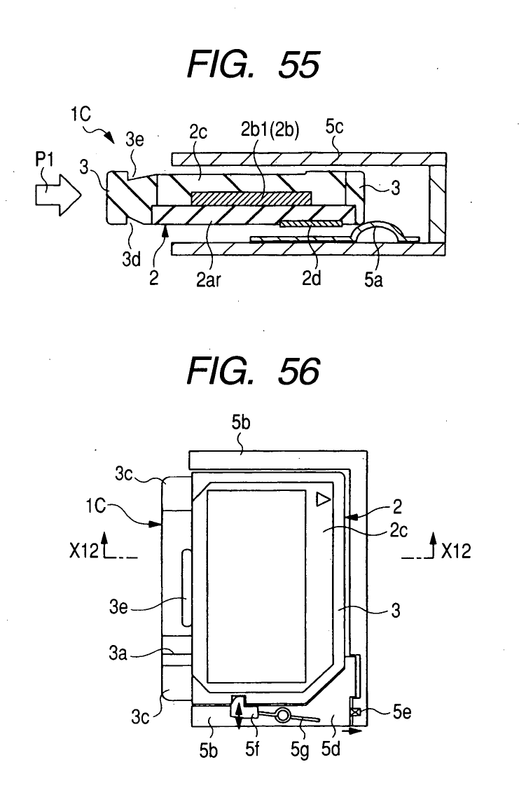

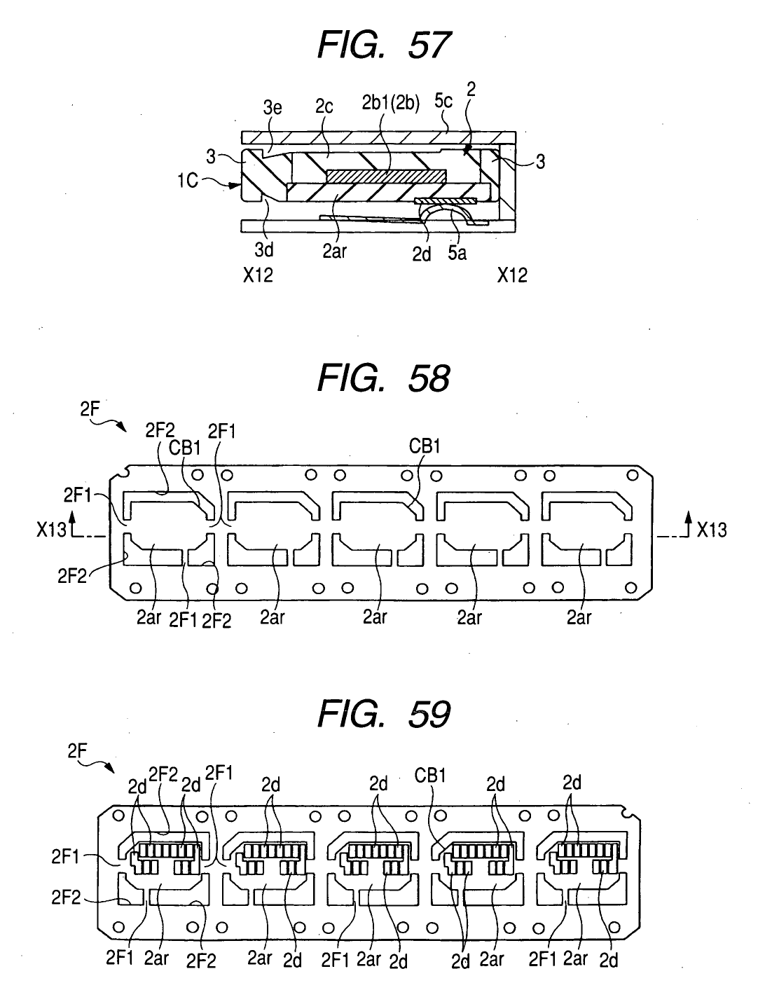

Subsequently explained with reference to FIGS. 53 to 57 is the state wherein the memory card 1C is mounted to the connector of the electronic device. FIG. 53 is a plan view of the memory card 1C before it is mounted to the connector, FIG. 54 is a sectional view taken along a line X11-X11 in FIG. 53, FIG. 55 is a sectional view of the memory card 1C that is further pushed from the state shown in FIG. 54 until the lower section of the front face of the memory card 1C is brought into contact with connector pins 5a, FIG. 56 is a plan view of the memory card 1C that is fully inserted into the connector 5, and FIG. 57 is a sectional view taken along a line X12-X12 in FIG. 56.

When the memory card 1C is inserted in the direction shown by an arrow P1 in FIGS. 53 and 54, the lower section of the buffer section 3 at the front face of the outer periphery of the memory card 1C is brought into contact with the connector pins 5a. The round taper is formed at the outer peripheral corner of the buffer section 3 as described above, and further, the buffer section 3 is softer than the sealing section 2c and wiring board 3 and the surface of the buffer section 3 is smoother than the surface of the sealing section 2c or the wiring board 3, so that, even if the buffer section 3 is brought into contact with the connector pins 5a, disadvantages can be reduced or prevented such as the metal plating on each connector pin 5a is scraped off or the connector pins 5a themselves are broken. Further, disadvantages can be reduced or prevented such as the guide rail 5b is scraped off or foreign matter are produced with the scrape of the guide rail 5b, upon inserting and removing the memory card 1C. Moreover, even if the upper corner at the front face of the memory card 1C is brought into contact with the upper shell 5c of the connector 5 when the memory card 1C is pushed upward by the urging force of the connector pins 5a, a disadvantage of giving a damage to the upper shell 5c can be reduced or prevented, since the buffer section 3 is also present at the upper corner of the front face of the memory card 1C.

Subsequently, when the memory card 1C is further inserted as shown in FIGS. 56 and 57, the external terminals 2d of the memory card 1C are electrically connected to the connector pins 5a as being brought into contact with each other, like the embodiment 1. Further, a tip end of a locking claw 5f of the connector 5 is fitted into the recess 3b at the side face of the memory card 1C. The locking claw 5f is urged toward the direction for pressing the memory card 1C by a coil spring 5g provided at the other end, thereby being capable of preventing the memory card 1C from dropping off or popping out from the connector 5.

Further, the memory card 1C is thin, so that a problem may occur in which the memory card 1C moves in the thickness direction by an external shock to thereby instantaneously disconnect (instantaneous disconnection) between the external terminals 2d of the memory card 1C and the connector pins 5a of the connector 5. To prevent this problem, it is conceivable to provide a member for preventing shakes in the thickness direction of the memory card. In this case, however, there is a problem in that the number of parts increases and the connector cost is increased. Also, the connector 5 tends to be more compact and lighter in weight, and therefore it is difficult to provide new parts and mechanisms. In contrast to this, in the embodiment 3, a resin part of the buffer section 3 is left at the bottom of the recess 3b of the memory card 1C. This part is pushed by the locking claw 5f, thereby being capable of preventing the memory card 1C from moving upward and downward in the thickness direction. Therefore, the defect of instantaneous disconnection can be prevented. Since a mechanical part for falling-off prevention of the memory card 1C also serves as a mechanism for preventing the memory card 1C from shaking, new parts and mechanisms do not need to be added. Therefore, the memory card of this embodiment will neither cause an increase in cost of the connector 5 nor hamper the trend to make the connector 5 more compact and lighter in weight.

The manner for drawing the memory card 1C is the same as that in the embodiment 1. In this case too, the memory card 1C can smoothly be drawn since the surface of the buffer section 3 is smooth. Further, in the case of the MMC whose outer appearance is formed of the sealing section 2c without using a cap, the friction coefficient of the sealing section 2c to the connector is great, so that it is necessary to provide great force to a spring used as an ejector for removing the MMC from the connector. However, if the spring is made to have great force as described above, the recess 3b provided at the memory card 1C does not sufficiently function as a stopper, since the force of the ejector spring is too strong, and hence, there may be a fear that the memory card 1C pops out excessively to the outside. On the other hand, the memory card 1C according to the embodiment 3 is provided with the buffer section 3 at the outer periphery, resulting in that the memory card 1C can smoothly be inserted into or drawn from the connector 5. Accordingly, it is unnecessary to give great force to the ejector spring, whereby there is no fear that the memory card 1C pops out excessively upon drawing the memory card 1C.

Subsequently, one example of the manufacturing method of the memory card 1C according to the embodiment 3 will be explained with reference to FIGS. 58 to 68 along a manufacturing flowchart shown in FIG. 19.

Firstly, a board frame 2F shown in FIGS. 58 and 59 is . . . prepared (step 100 in FIG. 19). FIG. 58 is an overall plan view of a main surface (first face) of the board frame 2F and FIG. 59 is an overall plan view of a back face (second face) of the board frame 2F of FIG. 20. The sectional view taken along a line X13-X13 in FIG. 58 is the same as FIG. 22. The board frame 2F is the same as that explained in the embodiment 1 except for the size of the wiring board 2ar.

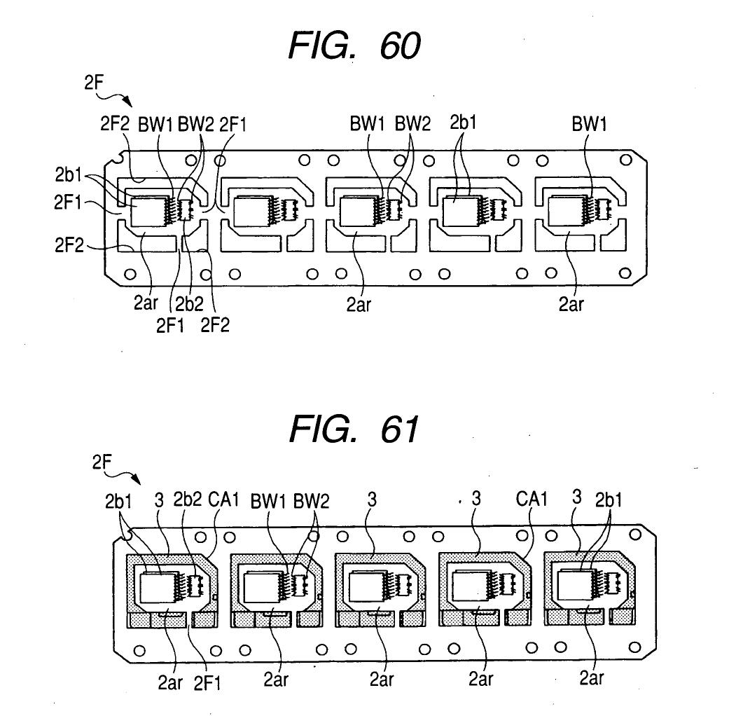

Subsequently, chips 2b1 and 2b2 are mounted (step 101 in FIG. 19) on the main surface of each wiring board 2ar of the board frame 2F as shown in FIG. 60. Then, pads PD1 and PD2 of the chips 2b1 and 2b2 on the main surface of each wiring board 2ar of the board frame 2F and wiring (electrode) on the main surface of the wiring board 2ar are electrically connected by wires BW1 and BW2 (step 102 in FIG. 19). FIG. 60 is an overall plan view of the main surface of the board frame 2F after the wire bonding process.

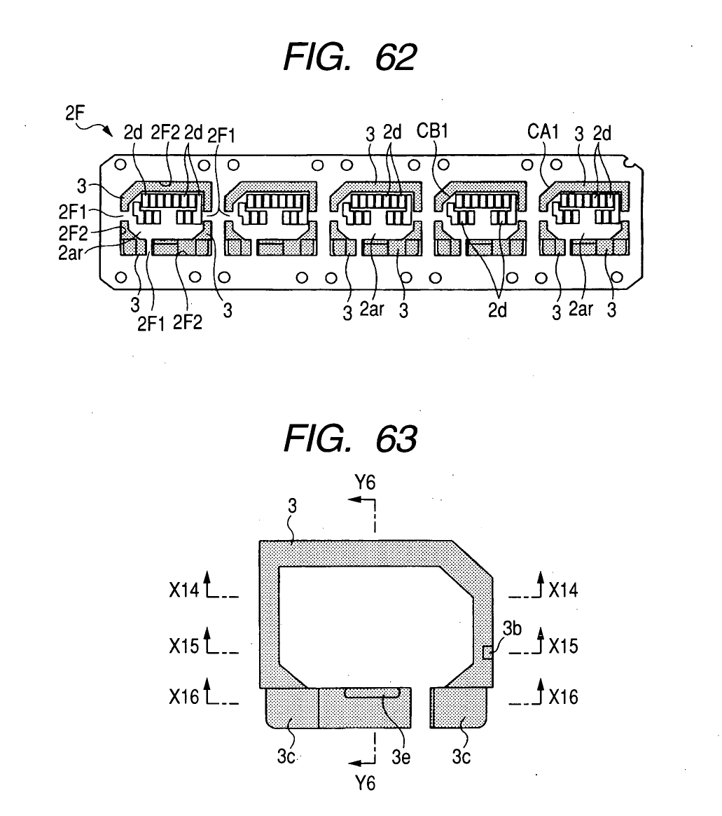

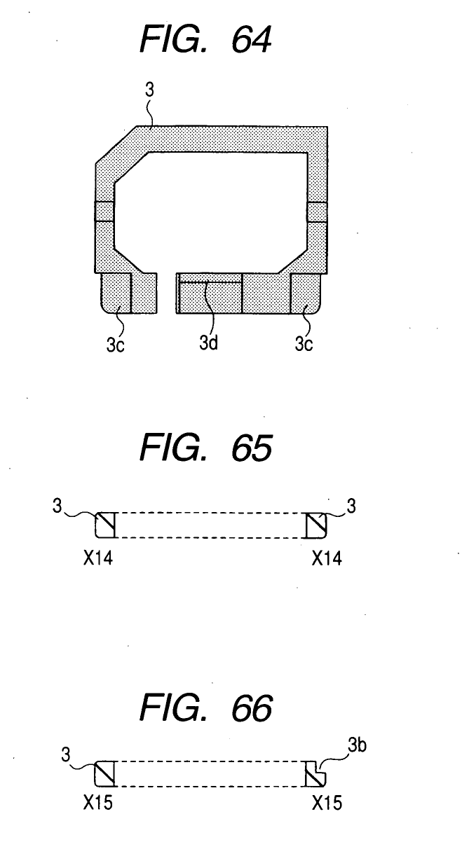

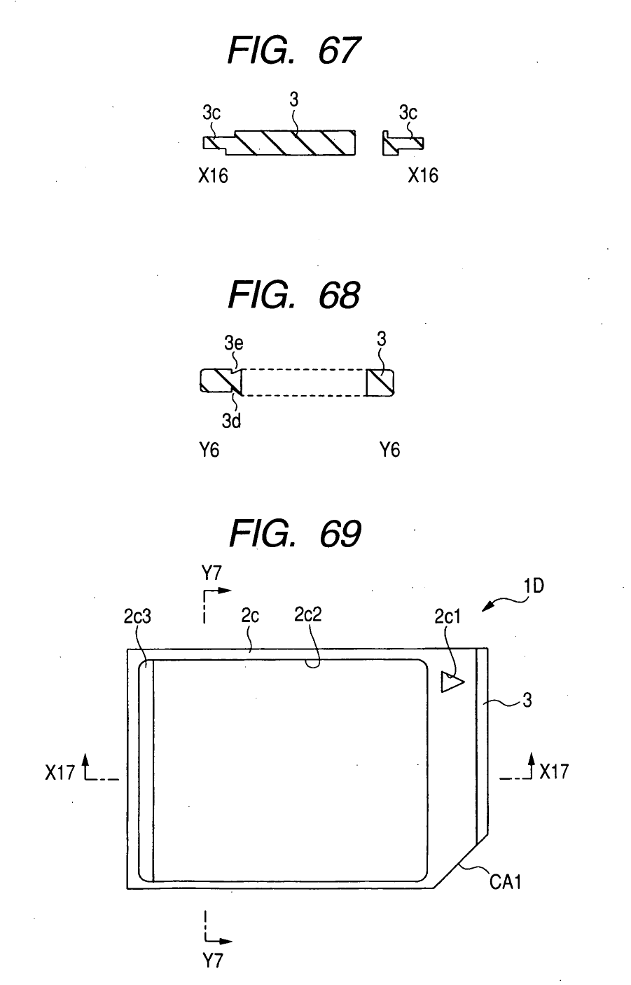

Subsequently, the buffer section 3 is mounted at the outer periphery of each wiring board 2ar of the board frame 2F (step 103 in FIG. 19) as shown in FIGS. 61 to 62. FIG. 61 is an overall plan view of the main surface of the board frame 2F after the buffer section 3 is mounted and FIG. 62 is an overall plan view of the back surface of the board frame 2F of FIG. 61. The buffer section 3 is mounted to the board frame 2F with its lower section fitted into the opening section 2F2 of the board frame 2F. FIGS. 63 to 68 show the buffer section 3 according to the embodiment 3. FIG. 63 is a plan view of the main surface of the buffer section 3, FIG. 64 is a plan view of the back face of the buffer section 3 in FIG. 63, FIG. 65 is a sectional view taken along a line X14-X14 in FIG. 63, FIG. 66 is a sectional view taken along a line X15-X15 in FIG. 63, FIG. 67 is a sectional view taken along a line X16-X16 in FIG. 63 and FIG. 68 is a sectional view taken along a line Y6-Y6 in FIG. 63. The complicated shape or minute concave/convex such as the recess 3b, adaptor mounting section 3c, adaptor claw attaching groove 3d, groove 3e and round taper at the corner have already been formed at the outer periphery of the buffer section 3 by a plastic injection molding.

After the mounting process of the buffer section 3, the mold process (step 104 in FIG. 19) and the dicing process (step 105 in FIG. 19) are performed by the same manner as in the embodiment 1, thereby fabricating the memory card 1C.

### Embodiment 4

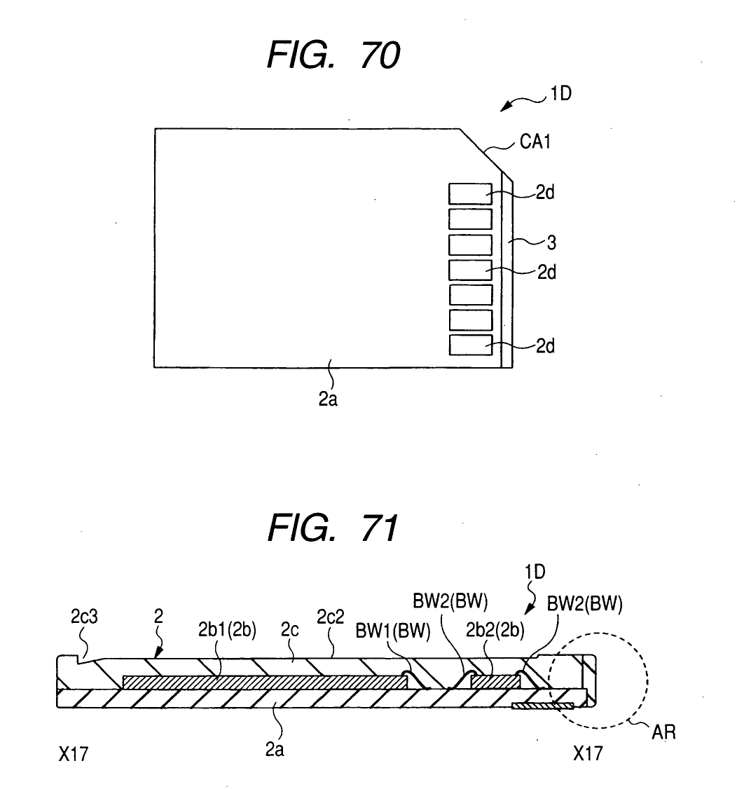

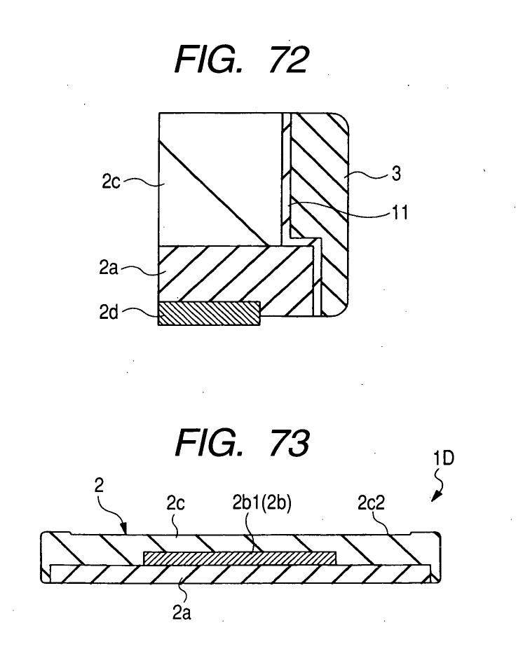

FIG. 69 is an overall plan view of a main surface of a memory card (IC card) 1D according to another embodiment of the present invention, FIG. 70 is an overall plan view of a back face of the memory card 1D shown in FIG. 69, FIG. 71 is a sectional view taken along a line X17-X17 in FIG. 69, FIG. 72 is an enlarged sectional view of an area AR in FIG. 71 and FIG. 73 is a sectional view taken along a line Y7-Y7 in FIG. 69.

The memory card 1D according to the embodiment 4 is provided with the buffer section 3 only at the front face of the outer periphery. This embodiment 4 illustrates the configuration wherein the buffer section 3 is bonded to the front face of the sealing section 2c and the wiring board 2a via the bonding agent 11. In this embodiment 4 too, a step is formed at the bonding face of the buffer section 3, wherein the step is fitly in place at the step formed by the side face of the sealing section 2c and the main surface of the wiring board 2a. Thus, the contact area between the buffer section 3 and the memory body 2 can be increased, thereby being capable of enhancing the bonding strength of the buffer section 3.

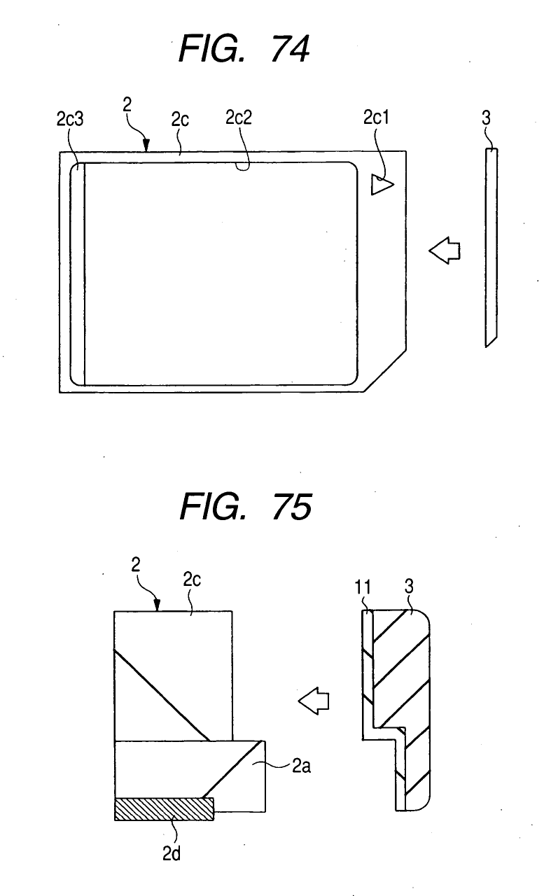

In order to fabricate the memory card 1D, the bonding agent 11 is applied on the bonding face of the buffer section 3, and then, the bonding face of the buffer section 3 is pressed against the front face of the memory body 2, as shown in FIGS. 74 and 75. Even if the buffer section 3 is formed only at a part of the outer peripheral face, not formed in a frame, like the embodiment 4, a memory card can be manufactured by the same manner as in the embodiments 1 to 3. Specifically, the resin for forming the sealing section 2 and the buffer section 3 may directly be bonded to each other upon the mold process of the sealing section 2c.

The embodiment 4 can reduce or prevent the deterioration or damage on the connector terminals due to the contact to the memory card 1D, when the memory card 1D is mounted to the connector of the electronic device.

Hereinbefore, though the invention made by the inventors has been described in detail based on preferred embodiments, it goes without saying that the present invention is not limited to the preferred embodiments, but may be modified in various ways without changing the main purports of the present invention.

For example, the buffer section may be provided only at both side faces of the memory card. This configuration can reduce or prevent the deterioration or damage on the guide rail of the connector due to the contact to the memory card, when the memory card is mounted to the connector of the electronic device.

Further, the buffer section may be provided at the front face and both side faces of the memory card. This configuration can reduce or prevent the deterioration or damage on the connector pins and the guide rail of the connector due to the contact to the memory card, when the memory card is mounted to the connector of the electronic device. The buffer section at the front face and the buffer section at both side faces of the memory card are integrally formed, whereby the facility on manufacturing the memory card can be enhanced, and further, the removal resistance can be enhanced.

Moreover, the embodiments 1 to 4 take a configuration wherein chips and a wiring board are electrically connected via a wire, but the invention is not limited thereto. The configuration may be adopted wherein chips and a wiring board are electrically connected via a bump electrode. In this case, chips are mounted on the wiring board via the bump electrode with its main surface facing to the main surface of the wiring board. The device of the main surface of the chip is connected to the wiring on the wiring board via the bump electrode, and further electrically connected to external terminals.

The above description has been dominated by application of the invention made by the inventors to a portable computer, digital camera or cellular phone, which is an application field of the invention. However, the present invention is not limited thereto. It can also be applied to another portable information processing devices such as, for example, PDA (Personal Digital Assistants).

The present invention can be applied to the IC card industry.

1. An IC card comprising:
(a) a card body; and
(b) a first resin section provided on at least a part of the outer peripheral face of the card body; wherein the card body comprising:
(a1) a wiring board having a first face and a second face that is the back face of the first face;
(a2) plural external terminals formed on the second face of the wiring board;
(a3) plural wirings formed on the wiring board;
(a4) a semiconductor chip mounted on the first face of the wiring board and electrically connected to the plural external terminals through the plural wirings; and
(a5) a second resin section that seals the semiconductor chip,
wherein a filler content included in the first resin section is less than a filler content included in the second resin section.

2. An IC card according to claim 1, wherein the first resin section is softer than the second resin section.

3. An IC card according to claim 1, wherein the surface of the first resin section is smoother than the surface of the second resin section.

4. An IC card according to claim 3, wherein the friction coefficient of the surface of the first resin section to the connector is less than the friction coefficient of the surface of the second resin section to the connector.

5. An IC card according to claim 1, wherein the first resin section is made into a frame encircling the outer periphery of the card body.

6. An IC card according to claim 1, wherein the first resin section is provided at the front face or side face of the outer periphery of the card body or at both of them.

7. An IC card according to claim 1, wherein a recess is formed at the first resin section.

8. An IC card according to claim 1, wherein the semiconductor chip and the plural wirings are electrically connected via a bonding wire.

9. An IC card according to claim 1, wherein plural semiconductor chips are laminated in the direction crossing the first face of the wiring board.

10. An IC card according to claim 1, wherein the semiconductor chip has a first semiconductor chip on which a memory circuit is formed and a second semiconductor chip on which a control circuit for controlling the memory circuit is formed.

11. An IC card according to claim 1, wherein the first resin section and the second resin section are different from each other in color.

12. An IC card comprising:
(a) a card body; and
(b) a first resin section provided on at least a part of the outer peripheral face of the card body,
the card body comprising:
(a1) a wiring board having a first face and a second face that is the back face of the first face;
(a2) plural external terminals formed on the second face of the wiring board;
(a3) plural wirings formed on the wiring board;
(a4) a semiconductor chip mounted on the first face of the wiring board and electrically connected to the plural external terminals through the plural wirings; and
(a5) a second resin section that seals the semiconductor chip,
wherein the first resin section is made of a thermoplastic resin and the second resin section is made of a thermosetting resin.

13. An IC card according to claim 12, wherein the filler content included in the first resin section is less than the filler content included in the second resin section.

14-20. (canceled)
